(19) United States
(12) Patent Application Publication
(10) Pub. No.: US 2026/0075848 A1
(43) Pub. Date: Mar. 12, 2026

(54) MEMORY DEVICE

(71) Applicant: Kioxia Corporation, Tokyo (JP)

(72) Inventors: Masaru SUZUKI, Kuwana (JP); Keisuke SUDA, Yokkaichi (JP)

(73) Assignee: Kioxia Corporation, Tokyo (JP)

(21) Appl. No.: 19/074,644

(22) Filed: Mar. 10, 2025

(30) Foreign Application Priority Data
Sep. 11, 2024 (JP) 2024-157585

(51) Int. Cl. H10B 80/00; H01L 23/00; H01L 25/00; H01L 25/065; H01L 25/18; H10B 41/27; H10B 43/27

(52) U.S. Cl. CPC H10B 80/00; H10B 41/27; H10B 43/27; H10W 90/00; H10W 80/312; H10W 80/327; H10W 90/792

(57) ABSTRACT

According to one embodiment, a device includes: a second chip bonded to a first chip. The second chip includes layers arranged in a first direction; a semiconductor layer above the layers in the first direction; a first contact penetrating the layers and including a portion located in the semiconductor layer; a second contact penetrating the layers and including a portion located in the semiconductor layer; and a member separating the semiconductor layer in a second direction between the contacts. The member includes a first portion located along a surface on a first chip side of the semiconductor layer and a second portion located along a surface on a side opposite to the first chip of the semiconductor layer. A first dimension along the second direction of the second portion is larger than a second dimension along the second direction of the first portion.

### CROSS-REFERENCE TO RELATED APPLICATIONS

This application is based upon and claims the benefit of priority from Japanese Patent Application No. 2024-157585, filed Sep. 11, 2024, the entire contents of which are incorporated herein by reference.

### FIELD Embodiments described herein relate generally to a memory device.

### BACKGROUND

A NAND flash memory is known as a memory device capable of storing data in a non-volatile manner.

### BRIEF DESCRIPTION OF DRAWINGS

FIG. 1 is a block diagram showing an example of an overall configuration of a memory device according to a first embodiment.

FIG. 2 is a circuit diagram of a memory cell array of the memory device according to the first embodiment.

FIG. 3 is a schematic diagram of a bonded structure of the memory device according to the first embodiment.

FIG. 4 is a cross-sectional view showing a structure example of the memory device according to the first embodiment.

FIG. 5 is a plan view showing a layout of the memory device according to the first embodiment.

FIG. 6 is a cross-sectional view showing a structure example of the memory cell array of the memory device according to the first embodiment.

FIG. 7 is a cross-sectional view showing a structure example of a memory pillar of the memory device according to the first embodiment.

FIG. 8 is a cross-sectional view showing a structure of a bonded pad of the memory device according to the first embodiment.

FIG. 9 is a cross-sectional view showing a structure example of a separation member of the memory device according to the first embodiment.

FIG. 10 is a plan view showing a structure example of contacts and the separation member of the memory device according to the first embodiment.

FIG. 11A is a cross-sectional view showing a structure example of the contact and the separation member of the memory device according to the first embodiment.

FIG. 11B is a cross-sectional view showing a structure example of the contact and the separation member of the memory device according to the first embodiment.

FIG. 12 is a cross-sectional process diagram showing a process of a method of manufacturing the memory device according to the first embodiment.

FIG. 13 is a cross-sectional process diagram showing a process of the method of manufacturing the memory device according to the first embodiment.

FIG. 14 is a cross-sectional process diagram showing a process of the method of manufacturing the memory device according to the first embodiment.

FIG. 15 is a cross-sectional process diagram showing a process of the method of manufacturing the memory device according to the first embodiment.

FIG. 16 is a cross-sectional process diagram showing a process of the method of manufacturing the memory device according to the first embodiment.

FIG. 17 is a cross-sectional process diagram showing a process of the method of manufacturing the memory device according to the first embodiment.

FIG. 18 is a cross-sectional process diagram showing a process of the method of manufacturing the memory device according to the first embodiment.

FIG. 19 is a cross-sectional process diagram showing a process of the method of manufacturing the memory device according to the first embodiment.

FIG. 20 is a cross-sectional process diagram showing a process of the method of manufacturing the memory device according to the first embodiment.

FIG. 21 is a cross-sectional process diagram showing a process of the method of manufacturing the memory device according to the first embodiment.

FIG. 22 is a cross-sectional process diagram showing a process of the method of manufacturing the memory device according to the first embodiment.

FIG. 23 is a cross-sectional process diagram showing a process of the method of manufacturing the memory device according to the first embodiment.

FIG. 24 is a cross-sectional process diagram showing a process of the method of manufacturing the memory device according to the first embodiment.

FIG. 25 is a cross-sectional process diagram showing a process of the method of manufacturing the memory device according to the first embodiment.

FIG. 26 is a cross-sectional process diagram showing a process of the method of manufacturing the memory device according to the first embodiment.

FIG. 27 is a cross-sectional process diagram showing a process of the method of manufacturing the memory device according to the first embodiment.

FIG. 28 is a cross-sectional process diagram showing a process of the method of manufacturing the memory device according to the first embodiment.

FIG. 29 is a cross-sectional process diagram showing a process of the method of manufacturing the memory device according to the first embodiment.

FIG. 30 is a cross-sectional process diagram showing a process of the method of manufacturing the memory device according to the first embodiment.

FIG. 31 is a cross-sectional process diagram showing a process of the method of manufacturing the memory device according to the first embodiment.

FIG. 32 is a plan view showing a structure example of a memory device according to a second embodiment.

FIG. 33 is a cross-sectional view showing a structure example of the memory device according to the second embodiment.

FIG. 34 is a cross-sectional view showing a structure example of a memory device according to a third embodiment.

FIG. 35 is a cross-sectional view showing a structure example of a contact and a separation member of the memory device according to a fourth embodiment.

FIG. 36 is a cross-sectional process diagram showing a process of a method of manufacturing the memory device according to the fourth embodiment.

FIG. 37 is a cross-sectional process diagram showing a process of the method of manufacturing the memory device according to the fourth embodiment.

FIG. 38 is a cross-sectional process diagram showing a process of the method of manufacturing the memory device according to the fourth embodiment.

FIG. 39 is a cross-sectional process diagram showing a process of the method of manufacturing the memory device according to the fourth embodiment.

FIG. 40 is a cross-sectional process diagram showing a process of the method of manufacturing the memory device according to the fourth embodiment.

FIG. 41 is a cross-sectional process diagram showing a process of the method of manufacturing the memory device according to the fourth embodiment.

FIG. 42 is a cross-sectional process diagram showing a process of the method of manufacturing the memory device according to the fourth embodiment.

FIG. 43 is a cross-sectional process diagram showing a process of the method of manufacturing the memory device according to the fourth embodiment.

FIG. 44 is a cross-sectional process diagram showing a process of the method of manufacturing the memory device according to the fourth embodiment.

FIG. 45 is a cross-sectional view showing a structure example of a memory device according to a fifth embodiment.

### DETAILED DESCRIPTION

In general, according to one embodiment, a memory device includes: a first chip including a substrate and a circuit on the substrate; and a second chip bonded to the first chip, wherein the second chip includes a layer stack including a plurality of conductive layers arranged apart from each other in a first direction perpendicular to a surface of the second chip, and a memory pillar penetrating the plurality of conductive layers, a first semiconductor layer provided above the layer stack in the first direction, the first semiconductor layer and a part of a source line being arranged in a second direction parallel to the surface of the second chip, a first contact that penetrates at least a first conductive layer among the plurality of conductive layers, is connected to the first conductive layer, and includes a portion located in the first semiconductor layer on a side opposite to the first chip with respect to the first conductive layer, a second contact that penetrates at least a second conductive layer among the plurality of conductive layers, is connected to the second conductive layer, and includes a portion located in the first semiconductor layer on a side opposite to the first chip with respect to the second conductive layer, the first contact and the second contact being arranged in the second direction, and a first separation member that separates the first semiconductor layer in the second direction between the first contact and the second contact, the first separation member includes a first portion located along a surface on a first chip side of the first semiconductor layer and a second portion located along a surface on a side opposite to the first chip of the first semiconductor layer, and a first dimension along the second direction of the second portion is larger than a second dimension along the second direction of the first portion.

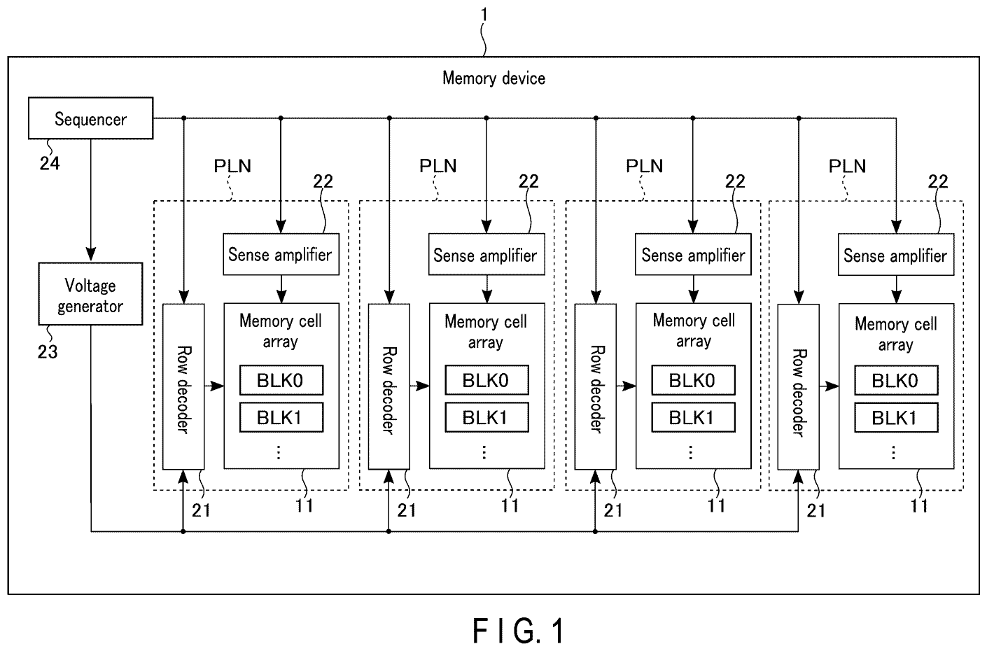

A memory device and a method of manufacturing the memory device according to an embodiment will be described with reference to FIGS. 1 to 45. In the following description, elements having the same function and configuration are denoted by the same reference numerals. Further, in each of the following embodiments, in a case where the components (for example, circuits, interconnects, various voltages and signals, and the like) with distinguishing reference numerals or letters in the end are not necessarily distinguished from each other, a description (reference numeral) in which the numerals or letters in the end are omitted is used.

### EMBODIMENTS

### (1) First Embodiment

A memory device and a method of manufacturing the memory device according to a first embodiment will be described with reference to FIGS. 1 to 31.

### (a) Configuration Example

(a-1) Overall Configuration of Memory Device

An example of an overall configuration of a memory device 1 according to the present embodiment will be described with reference to FIG. 1. FIG. 1 is a block diagram showing an overall configuration of the memory device 1 according to the present embodiment. In FIG. 1, some connections between the components are indicated by arrow lines, but the connections between the components is not limited thereto.

The memory device 1 is, for example, a three-dimensional stacked NAND flash memory. A three-dimensional stacked NAND flash memory includes a plurality of memory cells three-dimensionally arranged on a substrate (hereinafter, also referred to as a memory cell transistor).

As shown in FIG. 1, the memory device 1 of the present embodiment includes a plurality of planes PLN, a voltage generator 23, and a sequencer 24.

Each of the planes PLN is a circuit group that can operate independently of each other and in parallel (simultaneously). Each of the planes PLN includes a memory cell array 11, a row decoder 21, and a sense amplifier 22.

Each memory cell array 11 includes a plurality of blocks BLK. The block BLK is, for example, a set of a plurality of memory cells from which data is collectively erased. The memory cells are three-dimensionally arranged in the memory cell array 11. The memory cells in the block BLK are associated with rows and columns. Details of the internal configuration of the memory cell array 11 and the block BLK will be described later.

The row decoder 21 is a circuit that decodes a row address. The row address is an address signal that designates an interconnect in the row direction of the memory cell array 11. The row decoder 21 supplies a voltage used for the operation of the memory cell array 11 to the memory cell array 11 based on the decoding result of the row address.

The sense amplifier 22 is a circuit that writes and reads data. The sense amplifier 22 senses data read from the memory cell array 11 in the read operation. The sense amplifier 22 supplies a voltage corresponding to write data to the memory cell array 11 in the write operation.

The voltage generator 23 is a circuit that generates various voltages used for a write operation, a read operation, an erase operation, and the like. For example, the voltage generator 23 is connected to the row decoder 21 and the sense amplifier 22 of each plane PLN. The voltage generator 23 supplies the generated voltage to each row decoder 21 and each sense amplifier 22.

The sequencer 24 is a control circuit of the memory device 1. The sequencer 24 controls the entire operation of the memory device 1. For example, the sequencer 24 is connected to the row decoder 21, the sense amplifier 22, and the voltage generator 23. The sequencer 24 controls the row decoder 21, the sense amplifier 22, and the voltage generator 23. The sequencer 24 executes a write operation, a read operation, an erase operation, and the like on the memory cell array 11 under the control of an external controller (not shown).

Hereinafter, a circuit group for controlling the operation of the memory cell array 11, such as the row decoder 21, the sense amplifier 22, the voltage generator 23, and the sequencer 24, is also referred to as a CMOS circuit (or a peripheral circuit).

(a-2) Circuit Configuration of Memory Cell Array

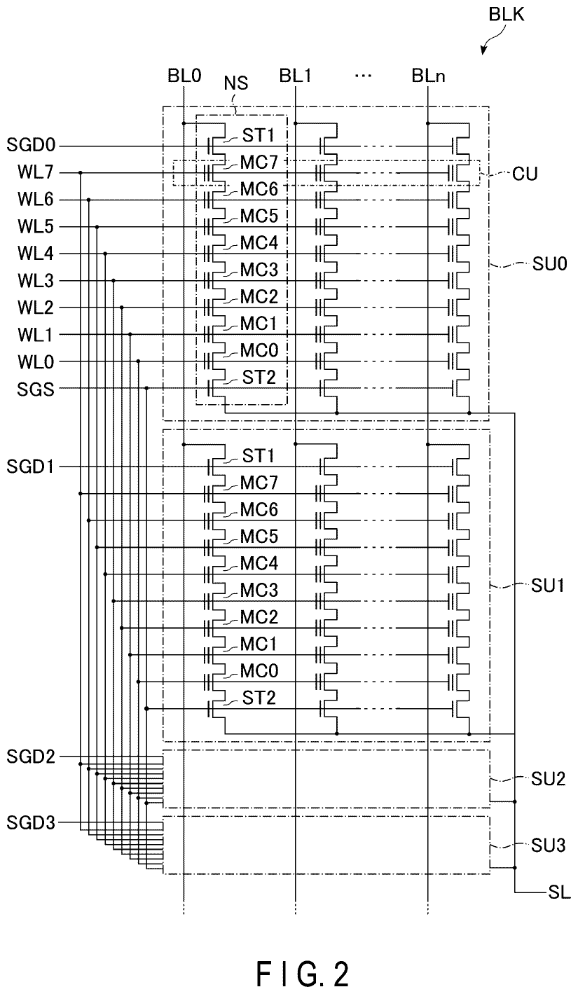

An example of a circuit configuration of the memory cell array 11 will be described with reference to FIG. 2. FIG. 2 is a circuit diagram of the memory cell array 11. The example of FIG. 2 shows a circuit configuration of one block BLK.

As shown in FIG. 2, the block BLK includes a plurality of string units SU. The string unit SU is, for example, a set of a plurality of NAND strings NS collectively selected in the write operation or the read operation. The NAND string NS includes a set of a plurality of memory cells MC connected in series. For example, one block BLK includes four string units SU0, SU1, SU2, and SU3.

Note that the number of blocks BLK in the memory cell array 11 and the number of string units SU in the block BLK are arbitrary.

Each NAND string NS includes a plurality of memory cells MC, a select transistor ST1, and a select transistor ST2. In the example of FIG. 2, the NAND string NS includes eight memory cells MC0, MC1, . . . , MC6, and MC7. Note that the number of memory cells MC included in the NAND string NS is arbitrary.

The memory cell MC is a memory element that stores data in a non-volatile manner. The memory cell MC is a transistor including a control gate and a charge storage layer. The memory cell MC may be a metal-oxide-nitride-oxide-silicon (MONOS) type transistor or a floating gate (FG) transistor. In a MONOS type memory cell transistor, an insulating layer such as a silicon nitride layer is used as a charge storage layer. In an FG-type memory cell transistor, a conductive layer such as a polysilicon layer is used as a charge storage layer. Hereinafter, a case where the memory cell MC is a MONOS type transistor will be described.

The select transistors ST1 and ST2 are switching elements. Each of the select transistors ST1 and ST2 is used to select the string unit SU in various operations of the memory device 1. The number of each of the select transistors ST1 and ST2 included in the NAND string NS is arbitrary. One or more select transistors ST1 and ST2 may be included in each of the NAND strings NS.

The current path of the select transistor ST2, the current paths of the memory cells MC0, . . . , and MC7, and the current path of the select transistor ST1 in the NAND string NS are connected in series. A drain of the select transistor ST1 is connected to a bit line BL. A source of the select transistor ST2 is connected to a source line SL.

Each of the control gates of the memory cells MC0, . . . , and MC7 in the same block BLK is connected to a corresponding one of the word lines WL0, . . . , and WL7. Each of the four string units SU includes a memory cell MC0.

The control gates of the memory cells MC0 in the block BLK are commonly connected to one word line WL0. The memory cells MC1, . . . , and MC7 are also connected to the corresponding word lines WL1, . . . , and WL7, respectively, similarly to the memory cells MC0.

Gates of the select transistor ST1 in the string unit SU are commonly connected to one select gate line SGD. More specifically, the gates of the select transistor ST1 in the string unit SU0 are commonly connected to a select gate line SGD0. Gates of the select transistor ST1 in the string unit SU1 are commonly connected to a select gate line SGD1. Gates of the select transistor ST1 in the string unit SU2 are commonly connected to a select gate line SGD2. Gates of the select transistor ST1 in the string unit SU3 are commonly connected to a select gate line SGD3.

Gates of the select transistor ST2 in the block BLK are commonly connected to one select gate line SGS.

Similarly to the select gate line SGD, a plurality of different select gate lines SGS may be provided in the block BLK for each string unit SU.

The word lines WL0, . . . , and WL7, the select gate lines SGD0, . . . , and SGD3, and the select gate line SGS are connected to the row decoder 21 respectively.

The bit lines BL are commonly connected to one NAND string NS in each string unit SU of each block BLK. The same column address is allocated to the NAND strings NS connected to one bit line BL. Each bit line BL is connected to the sense amplifier 22.

The source line SL is shared among the blocks BLK in one plane PLN, for example. The source line SL is independent for each plane PLN.

A set of the memory cells MC connected to the common word line WL in one string unit SU is referred to as, for example, a cell unit CU. For example, the write operation and the read operation are executed in units of cell units CU.

(a-3) Outline of Bonded Structure of Memory Device

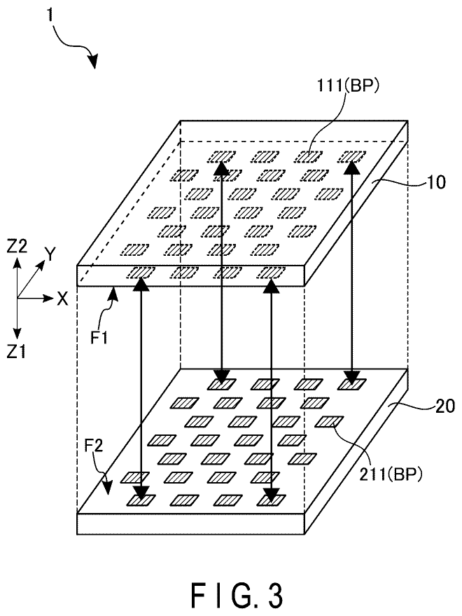

An outline of a structure of the memory device 1 according to the present embodiment will be described with reference to FIG. 3. FIG. 3 is a bird's-eye view showing an outline of a bonded structure of the memory device 1.

As shown in FIG. 3, the memory device 1 of the present embodiment includes two semiconductor chips 10 and 20.

One of the two semiconductor chips 10 and 20 is an array chip (also referred to as a memory cell array chip) 10. The array chip 10 is a chip provided with a plurality of memory cell arrays 11.

The other of the two semiconductor chips 10 and 20 is a CMOS circuit chip (also referred to as a CMOS chip) 20. The CMOS circuit chip 20 is a chip provided with a CMOS circuit for controlling the array chip 10.

The memory device 1 according to the present embodiment is formed by bonding the array chip 10 and the CMOS circuit chip 20. The memory device 1 has a structure in which the array chip 10 and the CMOS circuit chip 20 are bonded (hereinafter, referred to as a “bonded structure”). Hereinafter, in a case where the array chip 10 and the CMOS circuit chip 20 are not distinguished, each of the array chip 10 and the CMOS circuit chip 20 is simply referred to as a chip.

Note that a plurality of array chips 10 may be provided in the memory device 1. In this case, the array chips 10 may be stacked on the CMOS circuit chip 20. A plurality of CMOS circuit chips 20 may be provided in the memory device 1.

As shown in FIG. 3, the array chip 10 includes a plurality of pads (electrode, conductive layer, conductor) 111 on the surface F1. The CMOS circuit chip 20 includes a plurality of pads 211 on a surface F2. The pads 111 and 211 are used for bonding the two chips 10 and 20.

In the memory device 1 having the bonded structure, the surface F1 of the array chip 10 is attached to the surface F2 of the CMOS circuit chip 20. In this manner, the surface F1 of the array chip 10 on which the pads 111 are provided faces the surface F2 of the CMOS circuit chip 20 on which the pads 211 are provided. Hereinafter, the surfaces F1 and F2 on which the array chip 10 and the CMOS circuit chip 20 are bonded are also referred to as bonding surfaces BF.

In the bonded structure, the pads 111 of the array chip 10 and the pads 211 of the CMOS circuit chip 20 are bonded. With this configuration, bonded pads BP are formed in the memory device 1. In other words, the electrodes constituting the pads 111 provided on the array chip 10 are bonded to the electrodes constituting the pads 211 provided on the CMOS circuit chip 20. As a result, the bonded pads BP in the memory device 1 having the bonded structure is formed.

The bonded pads BP include an active pad and a dummy pad. The active pad functions as a path of a signal or a power supply during operation of the memory device 1. The active pad is electrically connected to any path of a signal and a power supply. The dummy pad does not function as a path of the signal or a path of the power supply during the operation of the memory device 1. The dummy pads are not electrically connected to the signal path and the power supply path.

Hereinafter, the surfaces (bonding surfaces BF) on which the array chip 10 and the CMOS circuit chip 20 are bonded are referred to as XY surfaces. Directions orthogonal to each other in the XY plane are referred to as an X direction and a Y direction. The X direction and the Y direction are directions parallel to the XY plane. A direction substantially perpendicular to the XY plane and from the array chip 10 toward the CMOS circuit chip 20 is referred to as a Z1 direction. A direction substantially perpendicular to the XY plane and from the CMOS circuit chip 20 toward the array chip 10 is referred to as a Z2 direction. In a case where the Z1 direction and the Z2 direction are not distinguished, the direction substantially perpendicular to the XY plane is referred to as a Z direction.

(a-4) Structure of Memory Device

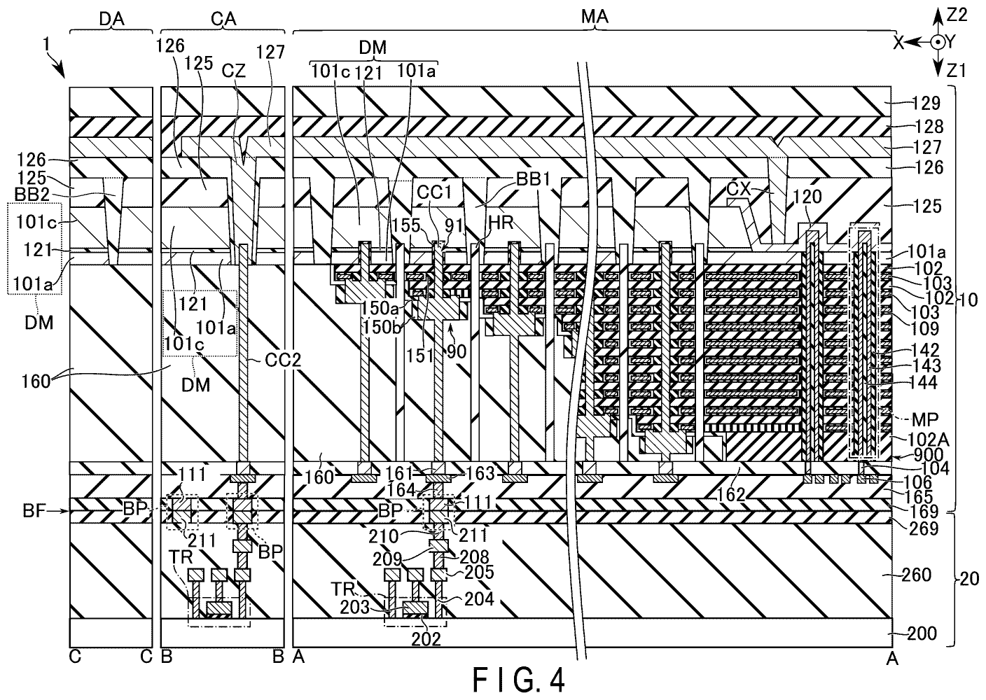

An example of a structure of the memory device 1 according to the present embodiment will be described with reference to FIG. 4. FIG. 4 is a cross-sectional view showing an example of a cross-sectional structure of the memory device 1. In FIG. 4, main parts of the components of the memory device 1 according to the present embodiment are extracted and shown.

As described above, the memory device 1 according to the present embodiment shown in FIG. 4 has a bonded structure of the array chip 10 and the CMOS circuit chip 20.

The array chip 10 includes memory pillars MP, semiconductor layers 101a and 101c, insulating layers 102, 102A, 109, 121, 125, 126, 128, 129, 150 (150a and 150b), 160, 162, 165, and 169, an insulator 151, an insulating film 155, conductive layers (word lines and select gate line) 103, interconnects 106, 127, and 163, conductors 104, 161, and 164, contacts CX, CZ, CC1, and CC2, a metal layer 120, and electrodes (pads) 111.

The CMOS circuit chip 20 includes a semiconductor substrate 200, transistors TR, conductors (plugs) 204, 208, and 210, interconnects 205 and 209, electrodes (pads) 211, and insulating layers 260 and 269. The transistor TR includes a gate insulating layer 202, a gate electrode 203, and a source/drain layer (not shown).

The electrodes 111 and the electrodes 211 are used for the bonded pads BP. Contact surfaces of the insulating layer 169 and the insulating layer 269 are the bonding surfaces BF of the two chips 10 and 20.

(a-5) Structure of Array Chip

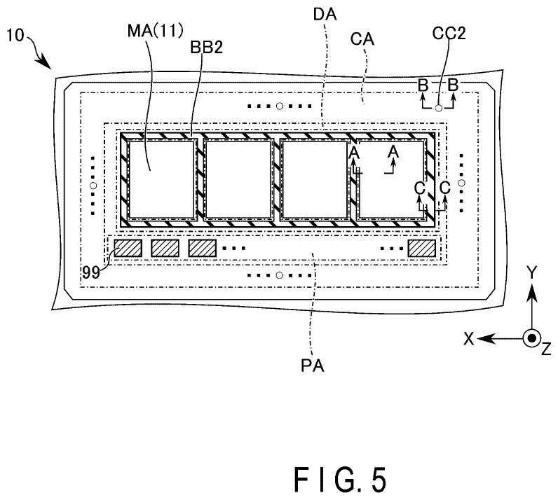

The structure of the array chip 10 in the memory device 1 according to the present embodiment will be described with reference to FIGS. 4 and 5.

The layout of the array chip 10 of the memory device 1 according to the present embodiment will be described with reference to FIG. 5.

FIG. 5 is a plan view showing a layout of a core region of the array chip 10 in the memory device 1 according to the present embodiment.

In the array chip 10 of the memory device 1, the core region includes a plurality of memory cell array areas MA, a contact area CA, a pad area PA, and a plane separation area DA.

In a case where the memory device 1 includes a plurality of planes PLNs, the array chip 10 includes a plurality of memory cell array areas MA. For example, the memory cell array areas MA are arranged in the X direction in the core region. Each of the memory cell array areas MA includes the memory cell array 11. Each memory cell array area MA is provided for each plane PLN.

The plane separation area DA partitions the memory cell array areas MA (memory cell arrays 11) for each plane PLN. The plane separation area DA surrounds each memory cell array area MA. The plane separation area DA separates the memory cell arrays 11 for each plane PLN. The plane separation area DA has a grid-like layout when viewed from the Z direction. The plane separation area DA is arranged between the two memory cell array areas MA, between the memory cell array area MA and the contact area CA, and between the memory cell array area MA and the pad area PA, respectively.

The plane separation area DA includes a grid-shaped slit (opening) when viewed from the Z direction. A separation member BB2 described later is provided in the slit. The separation member BB2 has a grid-like structure according to the shape of the slit. The slit and the separation member BB2 have a portion extending in the X direction and a portion extending in the Y direction.

The contact area CA is arranged in the core region so as to surround the periphery of the memory cell array areas MA. A plurality of contacts CC2 to be described later is provided in the contact area CA.

The pad area PA is disposed in a region between the contact area CA and the memory cell array area MA. The pad area PA includes a plurality of pads 99. For example, the pad 99 in the pad area PA is an external connection terminal. The pad 99 in the pad area PA is electrically connected to the contact CC2 in the contact area CA, the interconnect in the memory cell array area MA, the interconnect in the CMOS circuit chip 20, or the like.

Note that the array chip 10 further includes a kerf region (not shown) at an end of the array chip 10 and a peripheral region (not shown) between the kerf region and the core region. The kerf region includes a dicing area, an alignment mark, a characteristic check pattern, and the like. The peripheral region includes an edge seal and the like.

In FIG. 4, portions of the array chip 10 corresponding to the A-A line of the memory cell array area MA, the B-B line of the contact area CA, and the C-C line of the plane separation area DA in FIG. 5 are extracted and shown.

As shown in FIG. 4, in the memory cell array area MA, the semiconductor layer 101a extends in the X direction and the Y direction. The semiconductor layer 101a provided in the memory cell array area MA functions as a part of the source line SL. For example, the semiconductor layer 101a includes (contains) silicon.

In the memory cell array area MA, the insulating layers 102 and 102A and the conductive layers 103 are alternately stacked one by one on a surface facing the Z1 direction of the semiconductor layer 101a. A layer stack 900 including the insulating layers 102 and 102A and the conductive layers 103 is provided in the memory cell array area MA. The conductive layers 103 stacked apart from each other in the Z direction by the insulating layers 102 are provided between the CMOS circuit chip 20 and the semiconductor layer 101a. In the example of FIG. 4, ten insulating layers 102 and ten conductive layers 103 are alternately stacked one by one. The number of the insulating layers 102 and the number of the conductive layers 103 stacked in the Z direction are set according to the configuration of the memory cell array 11 (for example, the storage capacity).

Each of the conductive layers 103 extends in the X direction and functions as any of the word lines WL, the select gate line SGD, and the select gate line SGS. The conductive layer 103 includes, for example, a conductive material such as tungsten (W).

The insulating layer 102 separates the two conductive layers 103 adjacent to each other in the Z direction. The insulating layer 102 includes an insulating material such as silicon oxide. The thickness of the insulating layers 102A located closest to the CMOS circuit chip 20 among the insulating layers 102 and 102A is thicker than the thickness of the other insulating layers 102.

A plurality of memory pillars MP is provided in the memory cell array area MA. One memory pillar MP corresponds to one NAND string NS. The memory pillar MP has, for example, a cylindrical shape extending in the Z direction. The memory pillar MP penetrates (passes) the insulating layers 102 and 102A and the conductive layers 103.

The side surface (surface intersecting the XY plane) of the memory pillar MP faces the conductive layer 103. An end of the memory pillar MP in the Z2 direction penetrates the semiconductor layer 101a. The memory pillar MP includes a memory layer 142, a semiconductor layer 143, and a core layer 144. The semiconductor layer 143 extends in the Z direction. A part of the semiconductor layer 143 is in contact with the metal layer 120 on the semiconductor layer 101a. Details of the structure of the memory pillar MP will be described later.

For example, the insulating layer 109 such as aluminum oxide may be provided between the conductive layer 103 and the insulating layers 102 and 102A and between the conductive layer 103 and the memory pillar MP. Hereinafter, at the end in the Z direction of each member, the end on the Z2 direction side of the member is also referred to as an upper portion, and the end on the Z1 direction side of the member is also referred to as a bottom portion.

The metal layer 120 is provided on the semiconductor layer 101a. The metal layer 120 is electrically connected to the semiconductor layer 101a and the semiconductor layer 143 of the memory pillar MP. The metal layer 120 functions as the source line SL. As described above, the source line SL includes the metal layer 120 and the portion of the semiconductor layer 101a in contact with memory pillar MP.

The structure of the source line SL is not limited to the example in which the metal layer 120 is used. For example, the source line SL may have a structure in which the source line SL formed with the semiconductor layer is connected to the semiconductor layer 143 of the memory pillar MP via the opening formed in the memory layer 142 of the memory pillar MP. In this case, the semiconductor layer of the source line SL covers the end of the memory pillar MP.

For example, a slit (not shown) extending in the X direction is provided in the layer stack 900 including the insulating layers 102 and 102A and the conductive layers 103. An insulator (not shown) is filled inside the slit.

The insulator penetrates the insulating layers 102 and 102A and the conductive layers 103. For example, a region divided by the insulator (and the slit) corresponds to one block BLK. The slit is also used to supply the etching agent and the raw material of the conductive layer 103 into the layer stack 900 in the step of forming the conductive layer 103.

The conductor 104 is provided on the surface facing the Z1 direction of the memory pillar MP in the insulating layer 162. The conductor 104 has, for example, a cylindrical shape extending in the Z direction. The interconnects 106 are provided on a surface facing the Z1 direction of the conductor 104 in the insulating layer 165. The interconnects 106 are arranged in the X direction in the memory cell array area MA. Each of the interconnects 106 extends in the Y direction. Each of the memory pillars MP is electrically connected to any one of the interconnects 106 via the conductor 104. The interconnect 106 functions as the bit line BL. The interconnect 106 includes, for example, copper (Cu).

The end in the X direction of the layer stack 900 including the insulating layers 102 and 102A and the conductive layers 103 is processed in a stepwise manner. Hereinafter, a portion of the layer stack 900 processed in a stepwise manner is referred to as a staircase structure. The staircase structure is covered by the insulating layer 160. In the following description, a region in which the staircase structure is arranged in the memory cell array area MA is referred to as a hookup area.

In the staircase structure, the conductive layer 103 includes a portion (hereinafter, referred to as a terrace) that is not covered with the stacked insulating layer 102 and another conductive layer 103 other than itself on the Z1 direction side (in other words, a portion that does not overlap with the insulating layer 103). The conductive layer 103 is in contact with the contacts (contact plugs) CC1 on the terrace. Thus, the conductive layer 103 is electrically connected to the contacts CC1.

The contacts CC1 are provided in the hookup area of the memory cell array area MA. The contacts CC1 are arranged in the X direction and/or the Y direction. The contacts CC1 penetrate the insulating layer 102 and the conductive layer 103 in the staircase structure. The contact CC1 is a conductor. The contact CC1 has a cylindrical shape extending in the Z direction. The contact CC1 includes a portion 90 in contact with the terrace of the conductive layer 103. The contact CC1 includes a portion 91 reaching the semiconductor layers 101a and 101c and the insulating layer 121. Details of the structure of the contact CC1 will be described later.

The conductor (via plug) 161 is provided in the insulating layer 162. The interconnects 163 are provided in the insulating layer 165. The interconnect 163 is connected to the contact CC1 via the conductor 161. The interconnect 163 is electrically connected to the electrode 111 via the conductor 164 in the insulating layer 165, for example.

In the hookup area, a plurality of support members HR are provided. The support member HR penetrates the insulating layers 102 and the conductive layers 103 in the staircase structure. The support member HR has a cylindrical shape extending in the Z direction. The support member HR functions as a member for preventing collapse of the layer stack 900 in a process of forming the conductive layers 103 described later. The material of the support member HR is an insulator such as silicon oxide. Details of the structure of the support member HR will be described later.

In the insulating layer 160, an insulating layer 150b is provided on the side surface of the portion 90 of the contact CC1. An insulating layer 150a is provided between the insulating layer 150b and the insulating layer 109.

For example, the insulator 151 is provided between the contact CC1 and the side surface of the conductive layer 103. For example, the insulating film 155 is provided between the portion 91 of the contact CC1 and the semiconductor layers 101a and 101c.

The insulating layer 169 is provided on a surface facing the Z1 direction of the insulating layer 165. The electrodes 111 are provided in the same layer as the insulating layer 169. The electrodes 111 are disposed in the insulating layer 169. The electrodes 111 have a quadrangular shape when viewed from the Z direction. In the memory cell array area MA, the electrodes 111 are provided on a surface facing the Z1 direction of the conductor 164. The electrode 111 is electrically connected to one corresponding interconnect 163 among the interconnects 163. The electrode 111 is in contact with the corresponding electrode 211 of the CMOS circuit chip 20. The electrodes 111 and 211 function as a bonded pad BP. The electrode 111 includes copper. Note that the number of layers of the conductors 161 and 164 and the interconnect 163 provided between the electrode 111 and the contact CC1 is arbitrary.

The bonded pads BP include an active pad connected to the circuit and a dummy pad not connected to the circuit.

Although not shown in FIG. 4, the electrodes 111 electrically connecting the interconnect (bit line) 106 and the CMOS circuit chip 20 are provided in the memory cell array area MA.

The insulating layer 125 and the insulating layer 126 are stacked on the surface facing the Z2 direction of the semiconductor layer 101c and on the metal layer 120. The insulating layer 126 extends in the X direction and the Y direction on a surface facing the Z2 direction of the insulating layer 125. The insulating layer 125 is silicon oxide using SiH₄ as a raw material. The insulating layer 126 is silicon oxide.

The interconnect 127 is provided on the surface of the insulating layer 126 facing the Z2 direction. For example, in the memory cell array area MA, the interconnect 127 is electrically connected to the metal layer (source line) 120 via the contact (conductor) CX provided in the insulating layer 125 and 126. The contact CX is a member continuous with the interconnect 127. The contact CX is formed by embedding a member of the interconnect 127 in an opening formed in the insulating layers 125 and 126.

The insulating layers 128 and 129 are stacked on the surface facing the Z2 direction of the interconnect 127. The insulating layer 128 is provided between the insulating layer 129 and the interconnect 127. The material of the insulating layer 128 is silicon oxide using TEOS as a raw material. The material of the insulating layer 129 is silicon nitride.

For example, in a certain region (for example, the hookup area) of the memory cell array area MA, the contact area CA, and the plane separation area BA, the semiconductor layer 101c and the insulating layer 121 are provided between the semiconductor layer 101a and the insulating layer 125. The insulating layer 121 is provided between the semiconductor layer 101a and the semiconductor layer 101c. The material of the semiconductor layer 101c is, for example, silicon. The material of the insulating layer 121 is, for example, silicon oxide.

Hereinafter, the layer stack including the semiconductor layer 101a, the insulating layer 121, and the semiconductor layer 101c is referred to as a dummy layer DM. Note that a configuration further including the insulating layer 125 on the semiconductor layer 101c may be referred to as a dummy layer DM.

In the present embodiment, a separation member BB1 is provided in the dummy layer DM of the hookup area. The separation member BB1 separates the dummy layer DM into a plurality of portions. The separation member BB1 electrically separates the contacts CC1 arranged in the X direction and the contacts CC1 arranged in the Y direction. The separation member BB1 is disposed between the two adjacent contacts CC1. The separation member BB1 electrically separates the two contacts CC1 in the dummy layer DM. The separation member BB1 has a forward tapered cross-sectional shape. The forward tapered shape is a tapered shape in which a dimension along a direction (X direction or Y direction) parallel to the chip surface of the member decreases from the Z2 direction side toward the Z1 direction side. Details of the structure of the separation member BB1 will be described later.

For example, the separation member BB1 is further provided at the boundary between the hookup area and the area including the memory pillars MP (the end of the hookup area).

The contact area CA of the array chip 10 will be described.

The contact area CA includes semiconductor layers 101a and 101c and an insulating layer 121. The insulating layer 121 is provided between the two semiconductor layers 101a and 101c. The semiconductor layer 101a is provided on a surface of the insulating layer 160 facing the Z2 direction. The insulating layer 121 is provided on the semiconductor layer 101a. The semiconductor layer 101c is provided on the insulating layer 121. For example, the semiconductor layers 101a and 101c of the contact area CA are separated from the semiconductor layers 101a and 101c in the memory cell array area MA by the plane separation area DA.

The contacts (contact plugs) CC2 are provided in the contact area CA. The contacts CC2 are provided at a position corresponding to an opening provided in the dummy layer DM and the insulating layers 125 and 126. The contact CC2 mainly has a cylindrical shape extending in the Z direction in the insulating layer 160. An end of the contact CC2 in the Z2 direction protrudes from the insulating layer 160. The end of the contact CC2 in the Z2 direction is located in the layer of the dummy layer DM. The contact CC2 is used for electrical connection between the interconnect 127 and a component (for example, the transistor TR) in the CMOS circuit chip 20. The contact CC2 includes, for example, tungsten.

The interconnect 127 is electrically connected to the contact CC2 via the contact (conductor) CZ. The contact CZ is provided in the opening provided in the insulating layers 125 and 126 and the dummy layer DM. The contact CZ is a member continuous with the interconnect 127. The side surface of the contact CZ is covered with the insulating layer 126. The insulating layer 126 is provided between the side surface of the contact CZ and the dummy layer DM and between the side surface of the contact CZ and the insulating layer 125. The contact CZ is electrically separated from the dummy layer DM by the insulating layer 126.

In the contact area CA, the insulating layers 128 and 129 are stacked on the interconnect 127 and the insulating layer 126.

In the contact area CA, the electrodes (pads) 111 are provided in the insulating layer 169. In the contact area CA, each of the electrodes 111 has a quadrangular shape when viewed from the Z direction.

The electrode 111 is electrically connected to the contact CC2 via the conductors 161 and 164 and the interconnect 163. The conductors 161 are provided on a surface facing the Z1 direction of the contacts CC2. The interconnects 163 are provided on a surface facing the Z1 direction of the conductor 161. The conductors 164 are provided on a surface facing the Z1 direction of the interconnects 163.

The configurations of the conductors 161 and 164 and the interconnects 163 for connecting the contacts CC2 and the electrodes 111 are not limited to the example of FIG. 5. The number of conductors 161 and 164 between the contacts CC2 and the electrodes 111 and the number of interconnects 163 between the contacts CC2 and the electrodes 111 can be appropriately changed.

The electrode 111 electrically connects the array chip 10 and the CMOS circuit chip 20. The electrode 111 is in contact with the corresponding electrode 211 of the CMOS circuit chip 20. With this configuration, the bonded pad BP is formed in the contact area CA.

The plane separation area DA of the array chip 10 will be described.

A layer (dummy layer DM) including the semiconductor layers 101a and 101c and the insulating layer 121 is provided on a surface facing the Z2 direction of the insulating layer 160 in the plane separation area DA.

The semiconductor layers 101a and 101c and the insulating layer 121 in the plane separation area DA are not used as paths for electrically connecting the memory cell array 11 to other components. However, the semiconductor layers 101a and 101c of the plane separation area DA may include portions continuous with the semiconductor layers 101a and 101c of the memory cell array area MA.

The insulating layers 125 and 126 are stacked on a surface facing the Z2 direction of the semiconductor layer 101c. The interconnect 127 may be provided on the insulating layer 126 in the plane separation area DA.

In the plane separation area DA, the insulating layers 128 and 129 are stacked above the insulating layer 126 via the interconnect 127.

In the plane separation area DA, the separation member (insulator) BB2 is provided. For example, the separation member BB2 is provided in a slit (opening) formed in the plane separation area DA. The slit is provided in the semiconductor layer 101a, the insulating layer 121, the semiconductor layer 101c, and the insulating layer 125. The slit is filled with an insulator as the separation member BB2. The separation member BB2 is adjacent to the semiconductor layers 101a and 101c and the insulating layer 121 in the X direction (or the Y direction).

In a certain region between the two memory cell array areas MA, the separation member BB2 may be provided between the semiconductor layers 101a and 101c belonging to the respective memory cell array areas MA. The insulator as the separation member BB2 separates the semiconductor layer 101a (and the semiconductor layer 101c) in one memory cell array 11 from the semiconductor layer 101a (and the semiconductor layer 101c) in the other memory cell array 11 between the two adjacent memory cell arrays 11. Between the memory cell array area MA and the contact area CA, the separation member BB2 is provided between the semiconductor layer 101a (and the semiconductor layer 101c) and the dummy layer DM. The insulator as the separation member BB2 separates the semiconductor layer 101a (and the semiconductor layer 101c) from the dummy layer DM.

The separation member BB2 has a tapered cross-sectional shape. The tapered shape of the separation member BB2 is a forward tapered shape. Details of the structure of the separation member BB2 will be described later.

The insulator used for the separation member BB2 is a member continuous with the insulating layer 126. The insulator as the separation member BB2 is a portion (protruding portion) protruding from the insulating layer 126 in the Z1 direction. The end on the Z1 direction side of the insulator as the separation member BB2 is in contact with the insulating layer 160. The material of the separation member BB2 is the same as the material of the insulating layer 126 (for example, silicon oxide).

The separation member BB2 may be a member that is not continuous with the insulating layer 126. The separation member BB2 may include an insulating material different from the material of the insulating layer 126. A gap (void) may be provided inside the separation member BB2.

As described above, the separation member BB2 separates the semiconductor layer 101a (and the semiconductor layer 101c) included in the source line SL of the memory cell array area MA into a plurality of portions (the plurality of memory cell arrays 11) for each plane PLN. The semiconductor layer 101a (and the semiconductor layer 101c) included in the source line SL is independent of a portion of each memory cell array 11. As a result, the memory cell arrays 11 corresponding to the respective planes PLN are provided in the array chip 10.

(a-6) Structure of CMOS Circuit Chip

A cross-sectional structure of the CMOS circuit chip 20 in the memory device 1 according to the present embodiment will be described.

As shown in FIG. 4, the CMOS circuit chip 20 includes the semiconductor substrate 200. In the CMOS circuit chip 20, the transistors TR are provided on a surface facing the Z2 direction of the semiconductor substrate 200. The transistor TR is used as a component of the row decoder 21, the sense amplifier 22, the voltage generator 23, and the sequencer 24. The transistor TR includes the gate insulating layer 202, the gate electrode 203, and the source/drain layer (not shown). The gate insulating layer 202 is provided on a surface facing the Z2 direction of the semiconductor substrate 200. The gate electrode 203 is provided on the gate insulating layer 202. The source/drain layer is provided in the semiconductor substrate 200.

The insulating layer 260 is provided on a surface facing the Z2 direction of the semiconductor substrate 200. The insulating layer 260 covers the transistors TR, the conductors 204, 208, and 210, and the interconnects 205 and 209. For example, the insulating layer 260 has a stacked structure (multilayer interconnect structure) including a plurality of insulating films. Note that the number of layers of the interconnects provided in the CMOS circuit chip 20 is arbitrary.

The insulating layer 269 is provided on a surface facing the Z2 direction of the insulating layer 260. The surface facing the Z2 direction of the insulating layer 269 is in contact with, for example, the surface facing the Z1 direction of the insulating layer 169. Surfaces of the insulating layer 269 and the insulating layer 169 in contact with each other correspond to the bonding surfaces BF of the two semiconductor chips 10 and 20.

The electrodes (pads) 211 are provided in the insulating layer 269. The electrode 211 is connected to the electrode 111 and the conductor 210. For example, the electrode 211 has a quadrangular shape when viewed from the Z direction.

As a result, the transistor TR on the semiconductor substrate 200 is electrically connected to the memory cell array 11 of the array chip 10 or the contacts CC1 and CC2 of the array chip 10.

The gate electrode 203, the conductors 204, 208, and 210, the interconnects 205 and 209, and the electrodes 211 include, for example, a conductive material such as a metal or a semiconductor. The electrode 211 includes, for example, copper. The gate insulating layer 202 and the insulating layers 260 and 269 include, for example, an insulating material such as silicon oxide.

(a-7) Structure of Memory Cell Array

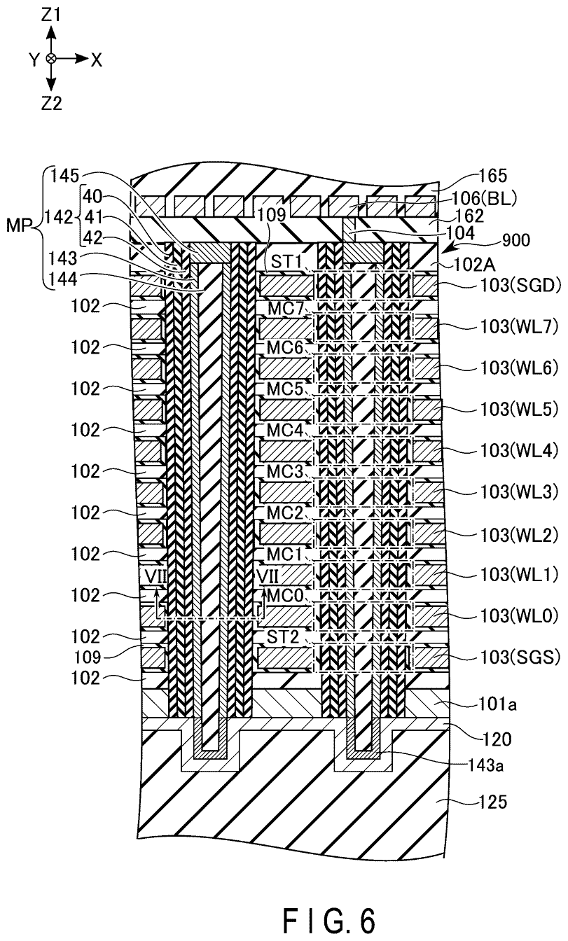

The cross-sectional structure of the memory cell array 11 will be described in detail with reference to FIG. 6. FIG. 6 is a cross-sectional view showing an example of a cross-sectional structure of the memory cell array 11. In FIG. 6, two memory pillars MP included in the memory cell array 11 are shown.

As shown in FIG. 6, the semiconductor layer 101a functions as a part of the source line SL. The semiconductor layer 101a contains, for example, silicon. The semiconductor layer 101a includes, for example, phosphorus (P) as an impurity of the semiconductor.

The insulating layers 102 (for example, ten layers) and the conductive layers 103 (for example, ten layers) are alternately stacked one by one on a surface of the semiconductor layer 101a facing the Z1 direction.

In the example of FIG. 6, each of the ten layers of conductive layers 103 functions as the select gate line SGS, the word lines WL0, WL1, . . . , WL6, and WL7, and the select gate line SGD in order from the side closer to the semiconductor layer 101a. Each of the select gate lines SGS and SGD may include the conductive layers 103.

For example, a stacked structure of titanium nitride (TiN)/tungsten (W) can be used as the conductive material of the conductive layer 103. In this case, titanium nitride is formed so as to cover tungsten. Titanium nitride has a function as a barrier layer for suppressing oxidation of tungsten and/or an adhesion layer for improving adhesion of tungsten, for example, at the time of forming tungsten by a chemical vapor deposition (CVD) method.

For example, the insulating layer 109 made of a high dielectric constant material such as aluminum oxide (AlO) is formed so as to cover the conductive layer 103 between the two stacked insulating layers 102. The insulating layer 109 is provided between the conductive layer 103 and the insulating layer 102 and between the conductive layer 103 and the memory pillar MP.

The memory pillars MP are provided in the memory cell array 11. The memory pillar MP extending in the Z direction penetrates the ten conductive layers 103. One end (an end in the Z2 direction) of the memory pillar MP in the Z direction penetrates the semiconductor layer 101a. The memory pillar MP may have a structure in which a plurality of pillars are connected in the Z direction.

An internal configuration of the memory pillar MP will be described. The memory pillar MP includes the memory layer 142, the semiconductor layer 143, the core layer 144, and a capping layer 145.

The memory layer 142 includes a block insulating layer 40, a charge storage layer 41, and a tunnel insulating layer 42. A side surface of the core layer 144 is covered with the block insulating layer 40, the charge storage layer 41, the tunnel insulating layer 42, and the semiconductor layer 143 in this order from the outside of the memory pillar MP.

The semiconductor layer 143 is provided so as to be in contact with the side surface of the tunnel insulating layer 42. The semiconductor layer 143 is a region in which current paths (channels) of the memory cell MC and the select transistors ST1 and ST2 are formed. The semiconductor layer 143 covers the side surface and the bottom surface of the core layer 144. At one end in the Z direction (an end portion in the Z2 direction) of the memory pillar MP, the block insulating layer 40, the charge storage layer 41, and the tunnel insulating layer 42 are removed. As a result, the semiconductor layer 143 is partially exposed. The impurity concentration of the exposed portion (hereinafter, referred to as an exposed portion) 143a of the semiconductor layer 143 is higher than the impurity concentration of the portion (hereinafter, referred to as a covering portion) of the semiconductor layer 143 covered with the memory layer 142. For example, the crystallinity of the exposed portion 143a of the semiconductor layer 143 is higher than the crystallinity of the covering portion of the semiconductor layer 143. The semiconductor layer 143 includes silicon.

The metal layer (source line) 120 is provided on the end (exposed portion) 143a on the Z2 direction side of the semiconductor layer 143 and on the semiconductor layer 101a. The metal layer 120 is in direct contact with the semiconductor layers 101a and 143 (143a).

The capping layer 145 is provided at the other end (an end in the Z1 direction) in the Z direction of the memory pillar MP so as to cover the respective ends on the Z1 direction side of the semiconductor layer 143 and the core layer 144. For example, the side surface of the capping layer 145 is in contact with the tunnel insulating layer 42. The capping layer 145 includes, for example, silicon.

The conductor 104 is provided on a surface facing the Z1 direction of the capping layer 145. The interconnects (bit lines) 106 are provided on a surface facing the Z1 direction of the conductor 104.

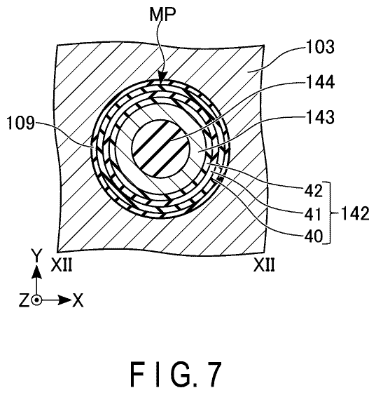

An example of a cross-sectional structure along the XY plane of the memory pillar MP (a planar structure viewed from the Z direction) will be described with reference to FIG. 7. More specifically, FIG. 7 illustrates a cross-sectional structure of the memory pillar MP in a hierarchy including the conductive layer 103.

In the cross section including the conductive layer 103, the core layer 144 is provided, for example, at the central portion of the memory pillar MP. The semiconductor layer 143 covers a side surface of the core layer 144. The tunnel insulating layer 42 covers the side surface of the semiconductor layer 143. The charge storage layer 41 covers a side surface of the tunnel insulating layer 42. The block insulating layer 40 covers a side surface of the charge storage layer 41. The conductive layer 103 covers the side surface of the block insulating layer 40. Each of the core layer 144, the tunnel insulating layer 42, and the block insulating layer 40 includes, for example, silicon oxide. The charge storage layer 41 has a function (property) of storing charges. The charge storage layer 41 includes, for example, silicon nitride.

For example, the insulating layer 109 including a metal oxide such as aluminum oxide (AlO) is provided between the conductive layer 103 and the block insulating layer 40.

The memory cell MC is configured by a combination of the memory pillar MP and the conductive layer 103 as the word line WL. The select transistor ST1 is configured by a combination of the memory pillar MP and the conductive layer 103 as the select gate line SGD. The select transistor ST2 is configured by a combination of the memory pillar MP and the conductive layer 103 as the select gate line SGS. As a result, each memory pillar MP can function as one NAND string NS.

(a-8) Cross-Sectional Structure of Bonded Pad

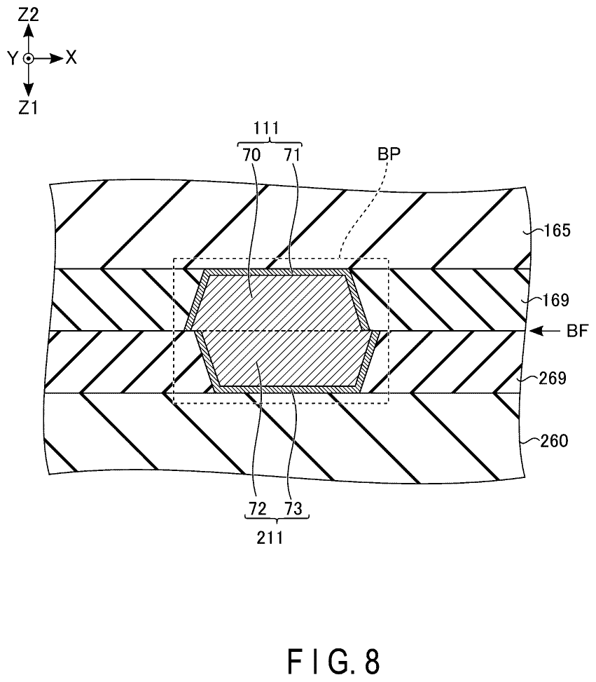

A cross-sectional structure of the bonded pad BP will be described with reference to FIG. 8. FIG. 8 is a cross-sectional view showing an example of a cross-sectional structure of the bonded pad BP. Note that, for simplification of description, FIG. 8 illustrates a structure of the bonded pad (dummy pad) BP that is not connected to a circuit.

As shown in FIG. 8, the electrode 111 includes a copper layer 70 and a barrier metal layer 71. The electrode 211 includes a copper layer 72 and a barrier metal layer 73.

In the process of bonding the array chip 10 and the CMOS circuit chip 20, the electrodes 111 are connected to the electrodes 211. In the example of FIG. 8, the area of the electrodes 111 and the area of the electrodes 211 on the bonding surfaces BF are substantially equal. In such a case, if copper is used for the electrode 111 and the electrode 211, the copper layer 70 of the electrode 111 and the copper layer 72 of the electrode 211 are integrated. With this configuration, regarding the two electrodes 111 and 211, it may be difficult to confirm the boundary of copper with each other. However, the bonding of the two semiconductor chips 10 and 20 can be confirmed by a distortion of the shape that the electrodes 111 and the electrodes 211 are bonded together due to the positional deviation of the bonding and/or the positional deviation of the barrier metal layers 71 and 73 (occurrence of a discontinuous portion on the side surface).

In a case where the electrode 111 and the electrode 211 are each formed by a damascene method, the side surfaces of the electrodes 111 and 211 have a tapered shape. For this reason, in the shape of the cross section of the bonded pad BP along the Z direction at the portion where the electrode 111 and the electrode 211 are bonded, the side wall (side surface) of the bonded pad BP is not linear and the shape of the cross section of the bonded pad BP is non-quadrangular.

In a case where the electrode 111 and the electrode 211 are bonded together, the barrier metal layers 71 and 73 cover the bottom surfaces of the copper layers 70 and 72 forming the bonded pad BP, the side surfaces of the copper layers 70 and 72, and the upper surfaces of the copper layers 70 and 72. On the other hand, in a general interconnect using copper, an insulating layer (SiN, SiCN, or the like) for preventing oxidation of copper is provided on the upper surface of copper, and a barrier metal is not provided on the upper surface of copper.

Therefore, even if the positional deviation of bonding does not occur, the bonded pad BP can be distinguished from a general interconnect layer.

(a-9) Structure of Plane Separation Area

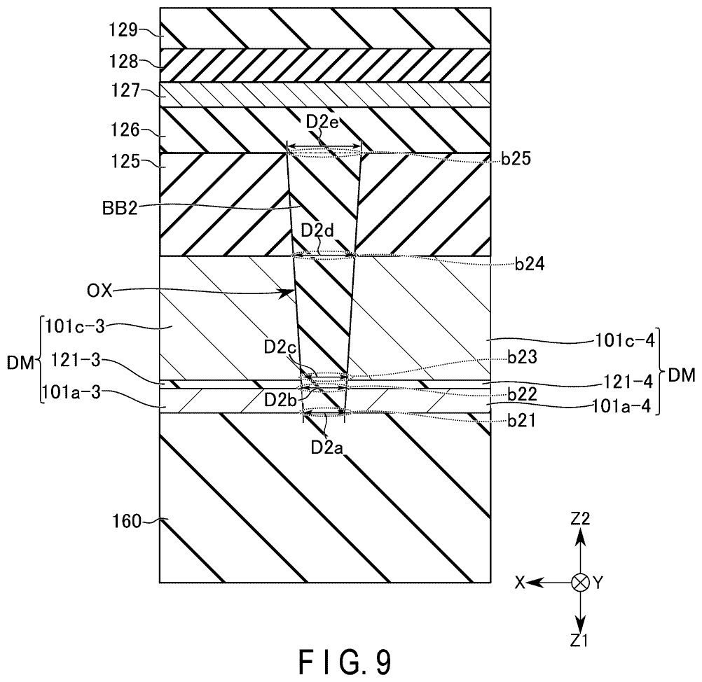

FIG. 9 is a cross-sectional view showing a structure of the separation member BB2 in the plane separation area DA.

As shown in FIG. 9, the separation member BB2 is provided in an opening OX formed in the layer stack including the insulating layer 125 and the dummy layer DM in the plane separation area DA. The separation member BB2 divides the semiconductor layers 101a and 101c and the insulating layer 121 of the dummy layer DM into a plurality of portions 101a-3, 101a-4, 101c-3, 101c-4, 121-3, and 121-4.

The separation member BB2 has a tapered cross-sectional shape. The tapered shape of the separation member BB2 is a forward tapered shape. The separation member BB2 includes a plurality of portions b21, b22, b23, b24, and b25 arranged in the Z direction.

The portion b21 is located at a position along the surface (lower surface) on the Z1 direction side of the semiconductor layer 101a. The portion b22 is located at a position along the surface (upper surface) on the Z2 direction side of the semiconductor layer 101a. The portion b23 is located at a position along the surface (lower surface) on the Z1 direction side of the semiconductor layer 101c. The portion b24 is located at a position along the surface (upper surface) on the Z2 direction side of the semiconductor layer 101c (position of the surface on the Z1 direction side of the insulating layer 125). The portion b25 is located at the position of the surface (upper surface) of the insulating layer 125 on the Z2 direction side.

With respect to the dimension in the line width direction of the portions b21 and b22 of the separation member BB2 in the semiconductor layer 101a, a dimension D2b along the X direction (or the Y direction) of the portion b22 is larger than a dimension D2a along the X direction (or the Y direction) of the portion b21.

With respect to the dimension in the line width direction of the portions b23 and b24 of the separation member BB2 in the semiconductor layer 101c, a dimension along the X direction (or the Y direction) D2d of the portion b24 is larger than a dimension D2c along the X direction (or the Y direction) of the portion b23.

With respect to the dimension in the line width direction of the portions b24 and b25 of the separation member BB2 in the insulating layer 125, a dimension D2e along the X direction (or the Y direction) of the portion b25 is larger than the dimension D2d along the X direction (or the Y direction) of the portion b24.

As described above, the dimension (line width) along the X direction (or the Y direction) of the separation member BB2 increases from the Z1 direction side toward the Z2 direction side.

Therefore, with respect to the separation member BB2 embedded in the layer stack including the dummy layer DM and the insulating layer 125, the dimension D2e in the direction along the surface of the chip of the separation member BB2 on the Z2 direction side is larger than the dimension D2a in the direction along the surface of the chip of the separation member BB2 on the Z1 direction side.

(a-10) Structure in Hookup Area

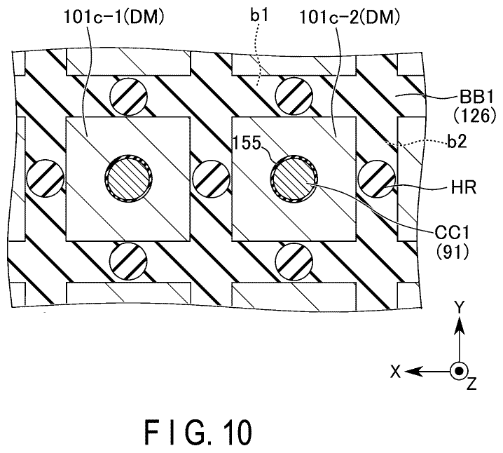

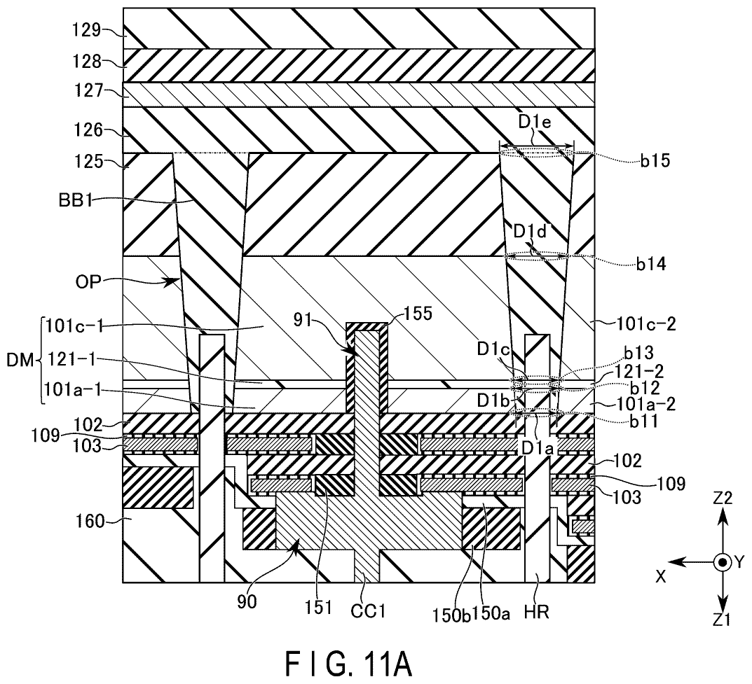

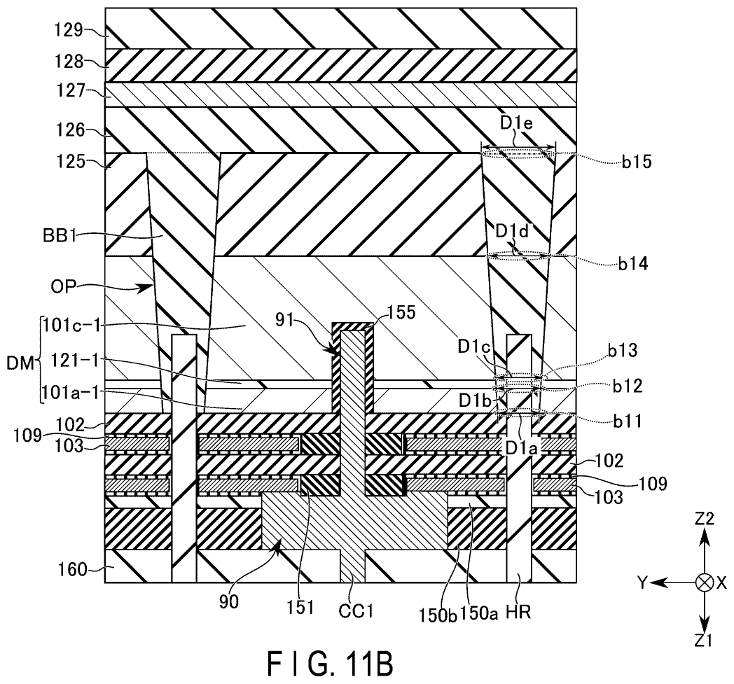

The structure of the components in the hookup area of the memory cell array area MA in the memory device 1 according to the present embodiment will be described with reference to FIGS. 10, 11A, and 11B.

FIG. 10 is a plan view showing structures of the contacts CC1 and the separation member BB1 in the hookup area of the memory cell array 11 in the memory device 1 according to the present embodiment. FIGS. 11A and 11B are cross-sectional views showing structures of the contact CC1 and the separation member BB1 in the hookup area of the memory cell array 11 in the memory device 1 according to the present embodiment. FIG. 11A illustrates a structure of the contact CC1 in the hookup area along the X direction and members in the vicinity of the contact CC1. FIG. 11B illustrates a structure of the contact CC1 in the hookup area along the Y direction and members in the vicinity of the contact CC1.

As shown in FIGS. 10, 11A, and 11B, in the hookup area, the contact CC1 penetrates one or more conductive layers 103 in the staircase structure. The contact CC1 penetrates the conductive layer 103 to be connected. The contact CC1 penetrates the other conductive layer 103 and the insulating layer 102 between the conductive layer 103 to be connected and the semiconductor layer 101a. For example, the contacts CC1 are arranged along the X direction (and the Y direction).

The contact CC1 includes a portion (hereinafter, also referred to as a projecting portion) 90 protruding in a direction (X direction and Y direction) parallel to the surface of the chip. The contact CC1 is in contact with the terrace of the corresponding conductive layer 103 by the projecting portion 90. At the contact portion between the conductive layer 103 and the projecting portion 90, the insulating layer 109 is removed from the conductive layer 103. As a result, the surface of the projecting portion 90 in the Z2 direction is in direct contact with the surface of the conductive layer 103 in the Z1 direction.

The side surface of the projecting portion 90 is covered with the insulating layer 150b. The insulating layer 150a is provided between the insulating layer 150b and the conductive layer 103 (insulating layer 109) in the Z direction. The insulating layer 109 is sandwiched between the insulating layer 150a and the conductive layer 103. The insulating layers 150a and 150b extend in the Y direction. The insulating layers 150a and 150b are members used at the time of forming the projecting portion 90 or products derived from the members. The material of the insulating layers 150a and 150b is silicon oxide.

The contact CC1 is electrically separated from the other conductive layer 103 other than the corresponding conductive layer (conductive layer to be connected) 103 by the insulator 151. The insulator 151 is provided between the side surface of the contact CC1 and the side surface of one or more conductive layers 103 through which the contact CC1 penetrates. The material of the insulator 151 is silicon oxide.

The contact CC1 includes a portion (hereinafter, also referred to as a protruding portion) 91 protruding into the dummy layer DM. For example, the protruding portion 91 of the contact CC1 penetrates the semiconductor layer 101a. An end (upper end) on the Z2 direction side of the contact CC1 is located in the semiconductor layer 101c. The diameter and the cross-sectional area in the direction parallel to the surface of the chip of the upper end of the contact CC1 may decrease from the Z1 direction side toward the Z2 direction side depending on the manufacturing process. Therefore, the contact CC1 tends to have a reversely tapered shape.

In the hookup area, the dummy layer DM is provided so as to overlap the staircase structure (layer stack 900) in the Z direction. As described above, the dummy layer DM includes the semiconductor layer (for example, a silicon layer) 101a, the insulating layer (for example, a silicon oxide layer) 121, and the semiconductor layer (for example, a silicon layer) 101c. The protruding portion 91 penetrates the semiconductor layer 101a and the insulating layer 121 of the dummy layer DM. The end of the protruding portion 91 in the Z2 direction reaches the semiconductor layer 101c of the dummy layer DM.

The insulating film 155 is provided between the dummy layer DM and the protruding portion 91 of the contact CC1. In the dummy layer DM, the insulating film 155 covers the protruding portion 91. The dummy layer DM is electrically separated from the contact CC1 by the insulating film 155. The material of the insulating film 155 is silicon oxide.

As described above, the support members (for example, a silicon oxide column) HR are provided in the hookup area. For example, each contact CC1 is provided in a region between two support members HR arranged in the X direction (or the Y direction). The contacts CC1 and the support members HR are alternately arranged in the X direction (or the Y direction).

The support member HR penetrates the one or more insulating layers 102 and the one or more conductive layers 103 in the staircase structure. The end of the support member HR in the Z2 direction reaches the layer in which the dummy layer DM is provided. The end of the support member HR in the Z2 direction is located in the layer provided with the semiconductor layer 101c in the Z direction. The support member HR adjacent to the contact CC1 in the X direction penetrates the insulating layer 150a. The support member HR adjacent to the contact CC1 in the Y direction penetrates the insulating layers 150a and 150b.

The memory device 1 according to the present embodiment includes the separation member BB1 in the hookup area. The separation member BB1 protrudes from the insulating layer 126 toward the staircase structure of the layer stack 900 in the Z direction. The separation member BB1 is continuous with the insulating layer 126. The separation member BB1 is an insulator. The material of the separation member BB1 is the same silicon oxide as the material of the insulating layer 126.

The separation member BB1 may be a member that is not continuous with the insulating layer 126. The separation member BB1 may include an insulating material different from the material of the insulating layer 126. A gap (void) may be provided inside the separation member BB1.

For example, the separation member BB1 has a grid-like layout when viewed from the Z direction. The separation member BB1 includes a portion b1 extending in the X direction and a portion b2 extending in the Y direction. The separation member BB1 is disposed in the hookup area so as to overlap with the support member HR in the Z direction. A portion of the dummy layer DM surrounded by the grid-like separation member BB1 has a quadrangular planar shape when viewed from the Z direction.

The separation member BB1 penetrates the insulating layer 125 and the dummy layer DM. The separation member BB1 is provided in the slit (opening) OP formed in the dummy layer DM and the insulating layer 125. The separation member BB1 is provided between the adjacent dummy layers DM in the X direction and the Y direction.

The separation member BB1 is disposed in a region between the two contacts CC1 arranged in the X direction (or the Y direction). The separation member BB1 comes into contact with the support member HR. For example, the separation member BB1 covers the side surface of the support member HR in the layer of the dummy layer DM.

The separation member BB1 has a tapered cross-sectional shape. The tapered shape of the separation member BB1 is a forward tapered shape similarly to the shape of the separation member BB2. The separation member BB1 is provided in the opening OP formed in the layer stack including the insulating layer 125 and the dummy layer DM. The separation member BB1 includes a plurality of portions b11, b12, b13, b14, and b15 arranged in the Z direction.

The portion b11 is located at a position along the surface (lower surface) on the Z1 direction side of the semiconductor layer 101a. The portion b12 is located at a position along the surface (upper surface) on the Z2 direction side of the semiconductor layer 101a. The portion b13 is located at a position along the surface (lower surface) on the Z1 direction side of the semiconductor layer 101c. The portion b14 is located at a position along the surface (upper surface) on the Z2 direction side of the semiconductor layer 101c (position of the surface on the Z1 direction side of the insulating layer 125). The portion b15 is located at the position along the surface (upper surface) of the insulating layer 125 on the Z2 direction side.

With respect to the dimension in the line width direction of the portions b11 and b12 of the separation member BB1 in the semiconductor layer 101a, a dimension D1b along the X direction (or the Y direction) of the portion b12 is larger than a dimension D1a along the X direction (or the Y direction) of the portion b11.

With respect to the dimension in the line width direction of the portions b13 and b14 of the separation member BB1 in the semiconductor layer 101c, a dimension D1d along the X direction (or the Y direction) of the portion b14 is larger than a dimension D1c along the X direction (or the Y direction) of the portion b13.

With respect to the dimension in the line width direction of the portions b14 and b15 of the separation member BB1 in the insulating layer 125, a dimension D1e along the X direction (or the Y direction) of the portion b15 is larger than the dimension D1d along the X direction (or the Y direction) of the portion b14.

As described above, the dimension (line width) along the X direction (or the Y direction) of the separation member BB1 increases from the Z1 direction side toward the Z2 direction side.

Therefore, with respect to the separation member BB1 embedded in the layer stack including the dummy layer DM and the insulating layer 125, a dimension D1e along the X direction (or the Y direction) on the Z2 direction side of the separation member BB1 is larger than the dimension D1a along the X direction (or the Y direction) on the Z1 direction side of the separation member BB1.

According to the forward tapered shape of the separation member BB1, the semiconductor layers 101a and 101c and the insulating layers 121 and 125 in the region surrounded by the separation member BB1 have a reverse tapered cross-sectional shape. The dimension along the X direction (or the Y direction) of the semiconductor layer 101a is larger than the dimension along the X direction (or the Y direction) of the insulating layer 125. For example, the dimension in the Z direction of the separation member BB1 is equal to the sum of the dimension in the Z direction of the dummy layer DM and the dimension in the Z direction of the insulating layer 125.

For example, the dimension D1e of the separation member BB1 is larger than the dimension D2e of the separation member BB2. For example, the dimension D1a of the separation member BB1 is larger than the dimension D2a of the separation member BB2.

In each of the portions (positions) b11, b12, b13, b14, and b15 in the Z direction of the separation member BB1, the dimension along the X direction of a certain portion in the Z direction of the separation member BB1 may be substantially the same as or different from the dimension along the Y direction of the portion of the separation member BB1.

According to the present embodiment, the separation member BB1 partitions the semiconductor layers 101a and 101c and the insulating layer 121 of the dummy layer DM into a plurality of portions 101a-1, 101a-2, . . . , 101c-1, 101c-2, . . . , 121-1, 121-2, . . . , for each contact CC1 reaching the dummy layer DM. As a result, the portions of the semiconductor layers 101a and 101c are electrically separated from each other. The semiconductor layers 101a and 101c surrounded by the separation member BB1 are not electrically connected to other members (for example, interconnects or pads) on the Z2 direction side.

In the memory device 1 according to the present embodiment, the contacts CC1 are electrically separated from each other by the separation member BB1 without being connected via the dummy layer DM.

### (b) Manufacturing Method

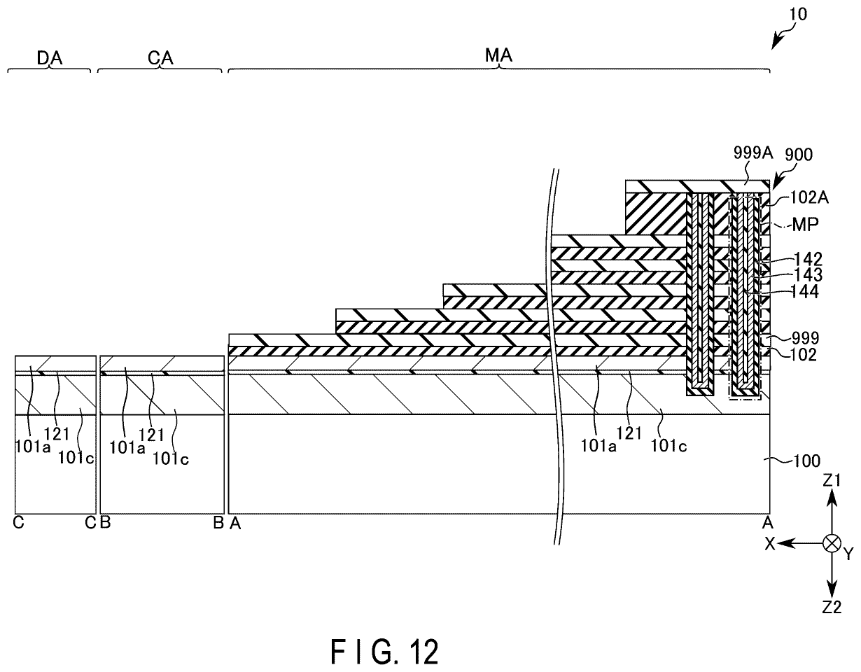

A method of manufacturing the memory device 1 according to the first embodiment will be described with reference to FIGS. 12 to 31. Each of FIGS. 12 to 23 is a cross-sectional process diagram showing a manufacturing process of the array chip 10 in the memory device 1 according to the present embodiment.

As shown in FIG. 12, on the first surface side facing the Z1 direction of the array chip 10, a semiconductor layer 101c such as a silicon layer is formed on a semiconductor substrate (for example, a silicon substrate) 100 by, for example, a CVD method. The insulating layer 121 such as a silicon oxide layer is formed on the semiconductor layer 101c. The semiconductor layer 101a such as a silicon layer is formed on the insulating layer 121.

The layer stack 900 including the insulating layers 102 and 102A and the sacrificial layers 999 is formed on the semiconductor layer 101a by the CVD method. In the layer stack 900, the insulating layers 102 and the sacrificial layers 999 are alternately deposited in the Z1 direction. The sacrificial layer 999 is a layer to be replaced with a conductive layer (word line and select gate line) 103 in a subsequent process. The insulating layers 102 and 102A are, for example, silicon oxide layers. The sacrificial layers 999 are, for example, silicon nitride layers.

In the layer stack 900, the film thickness in the Z direction of the uppermost insulating layer 102A is larger than the film thickness in the Z direction of the other insulating layers 102.

An insulating layer 999A is formed on the insulating layer 102A. The material of the insulating layer 999A is the same as the material of the sacrificial layers 999 (for example, silicon nitride).

In the hookup area of the array chip 10, the end of the layer stack 900 in the X direction is processed stepwise by photolithography and etching.

As a result, the staircase structure is formed in the hookup area. In the staircase structure, the surface (surface facing the Z1 direction) of each sacrificial layer 999 is exposed in a portion to be a terrace of the conductive layer 103.

In the contact area CA and the plane separation area DA, the insulating layers 102, 102A and 999A and the sacrificial layer 999 are removed.

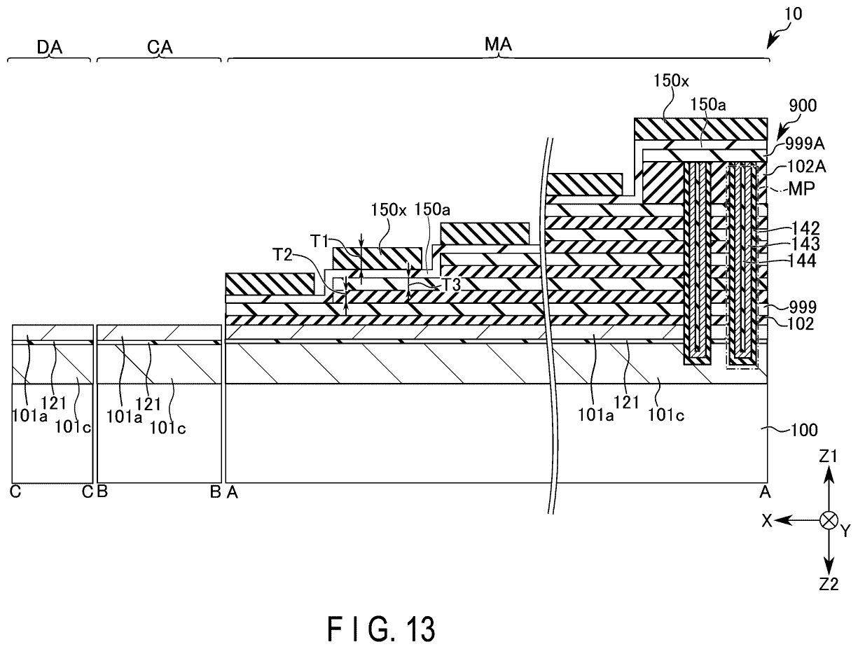

As shown in FIG. 13, the insulating layer 150a is formed on the insulating layers 102, 102A and 999A and the sacrificial layer 999 by the CVD method so as to cover the staircase structure. The insulating layer 150a covers sidewalls (steps) of the insulating layers 102, 102A and the sacrificial layer 999 in the hookup area. Hereinafter, the insulating layer 150a is also referred to as a sidewall spacer film. The material of the sidewall spacer film 150a is, for example, silicon oxide. For example, the film thickness in the Z direction of the sidewall spacer film 150a is substantially equal to the film thickness in the Z direction of the insulating layer 102.

A plurality of insulating layers 150x are formed on the sidewall spacer film 150a by the CVD method and etching. Each of the insulating layers 150x has a pattern independent of each other for each step (terrace) of the staircase structure. For example, the insulating layer 150x is arranged in a region corresponding to a contact portion between the terrace of the conductive layer 103 and the contact CC1 to be formed later. The insulating layer 150x extends in the Y direction. Hereinafter, the insulating layer 150x is referred to as a spacer film. The material of the spacer film 150x is, for example, the same as the material of the sacrificial layer 999 (for example, silicon nitride). For example, the film thickness T1 in the Z direction of the spacer film 150x is substantially equal to the total thickness of the film thickness T2 of one insulating layer 102 and the film thickness T3 of one sacrificial layer 999.

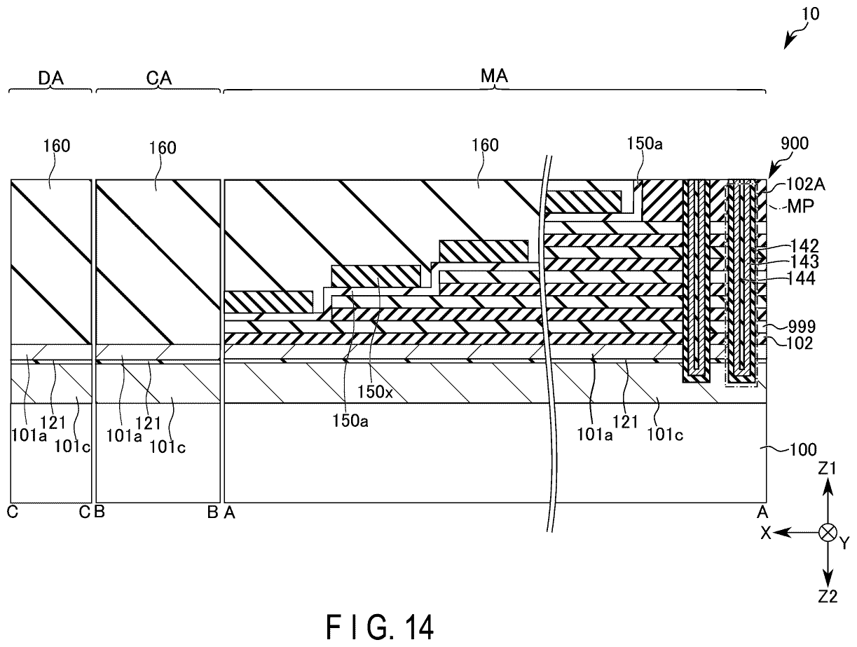

As shown in FIG. 14, in the memory cell array area MA, an insulating layer 160 such as a silicon oxide layer is formed on the sidewall spacer film 150a and the spacer film 150x by a CVD method using TEOS. The insulating layer 160 is planarized by a chemical mechanical polishing (CMP) method using the uppermost insulating layer 102A of the layer stack 900 as a stopper.

In the contact area CA and the plane separation area DA, the insulating layer 160 is formed on the semiconductor layer 101a.

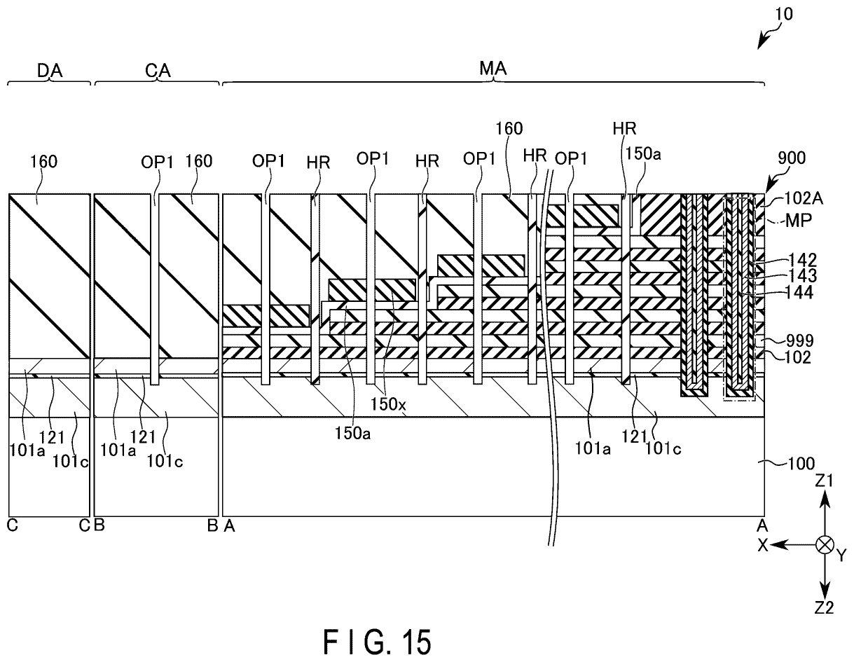

As shown in FIG. 15, in the hookup area of the memory cell array area MA, a plurality of openings are formed in a predetermined region of the insulating layer 160 by photolithography and etching. The lower ends of the openings reach the semiconductor layer 101c. After the openings are formed, the support members HR are formed in the openings. The support members HR penetrate the sidewall spacer film 150a and the staircase structure of the layer stack 900. The support members HR are formed of, for example, an insulator such as silicon oxide.

Among the support members HR, the support members HR located at the formation coordinates of the contacts CC1 are selectively removed. As a result, openings OP1 extending from the insulating layer 160 to the semiconductor layer 101c are formed at the formation coordinates of the contacts CC1 in the hookup area. For example, a part (not illustrated) of the support members HR may remain at the bottom of the opening OP1.

In the contact area CA, an opening OP1 whose bottom portion reaches the semiconductor layer 101c is similarly formed in the insulating layer 160 at the formation coordinate of the contact CC2.

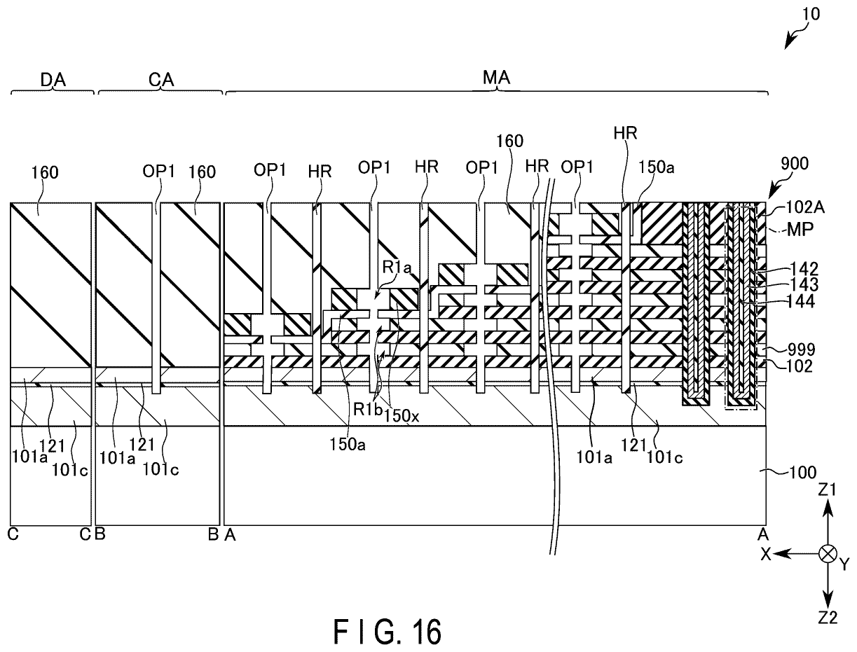

As shown in FIG. 16, etching is performed such that the spacer film 150x is selectively removed through the opening OP1.

With this process, the spacer film 150x retreats in a direction parallel to the surface of the semiconductor substrate 100. As a result, a recess (groove) R1a is formed in the opening OP1 corresponding to the position of the portion to be the terrace of the conductive layer 103 in the direction parallel to the surface of the semiconductor substrate 100. The recess R1a is formed corresponding to the position of the spacer film 150x between the insulating layer 160 and the insulating layer 150a.

The sacrificial layer 999 made of the same material as the spacer film 150x is etched (removed) simultaneously with the spacer film 150x.

At the position of the sacrificial layer 999, a recess R1b is formed corresponding to the space between the sidewall spacer film 150a and the insulating layer 102 or the space between the two insulating layers 102 adjacent in the Z direction.

Depending on the thickness of the spacer film 150x, the dimension in the Z direction of the recess R1a is larger than the dimension in the Z direction of the recesses R1b.

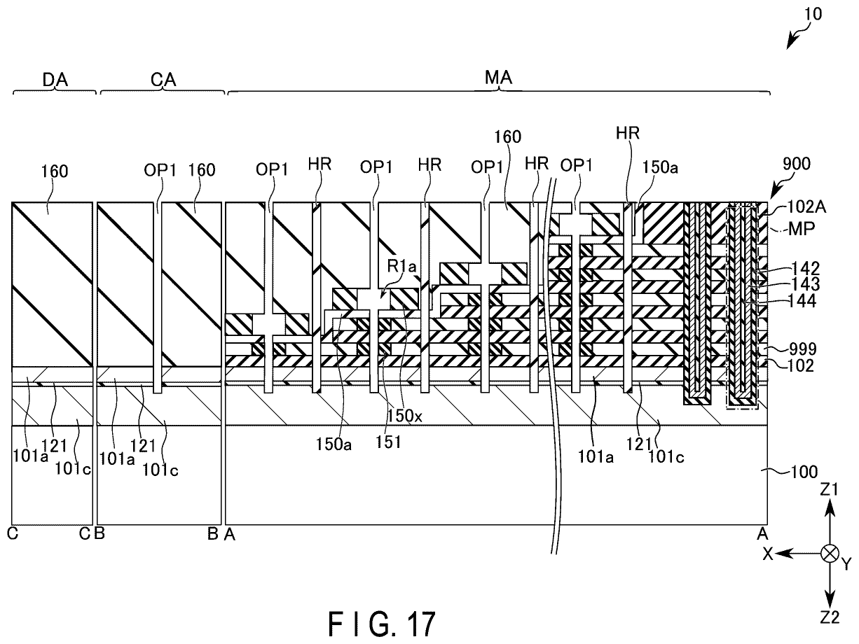

As shown in FIG. 17, the insulator 151 is formed in the opening OP1 including the recesses R1a and R1b. The insulator 151 is selectively etched by isotropic etching such as wet etching.

The insulator 151 is removed from the recess R1a having a large space. In the recess R1a, the spacer film 150x is exposed to the opening OP1.

On the other hand, the insulator 151 remains in the recess R1b having a space smaller than the recess R1a. The sacrificial layer 999 is sealed by the insulator 151 remaining in the recess R1b and is not exposed to the opening OP1.

For example, the insulator 151 is removed at the bottom of the opening OP1. The semiconductor layers 101a and 101c and the insulating layer 121 are exposed to the opening OP1.

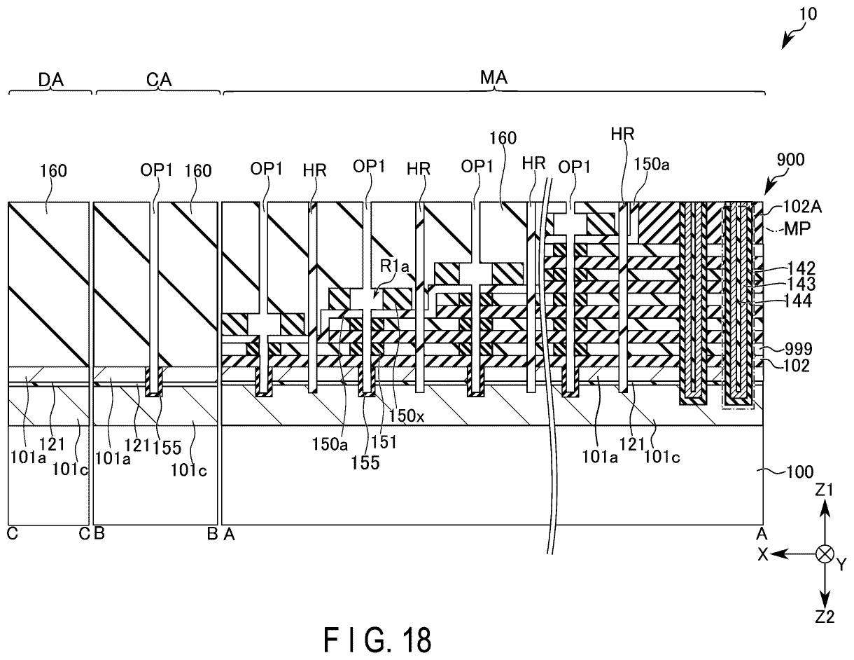

As shown in FIG. 18, the insulating film 155 is formed on the surfaces of the semiconductor layers 101a and 101c and the insulating layer 121 exposed through the opening OP1 by a water vapor generation (WVG) method.

For example, in the contact area CA, the insulating film 155 is formed on the exposed surfaces of the semiconductor layers 101a and 101c and the insulating layer 121.

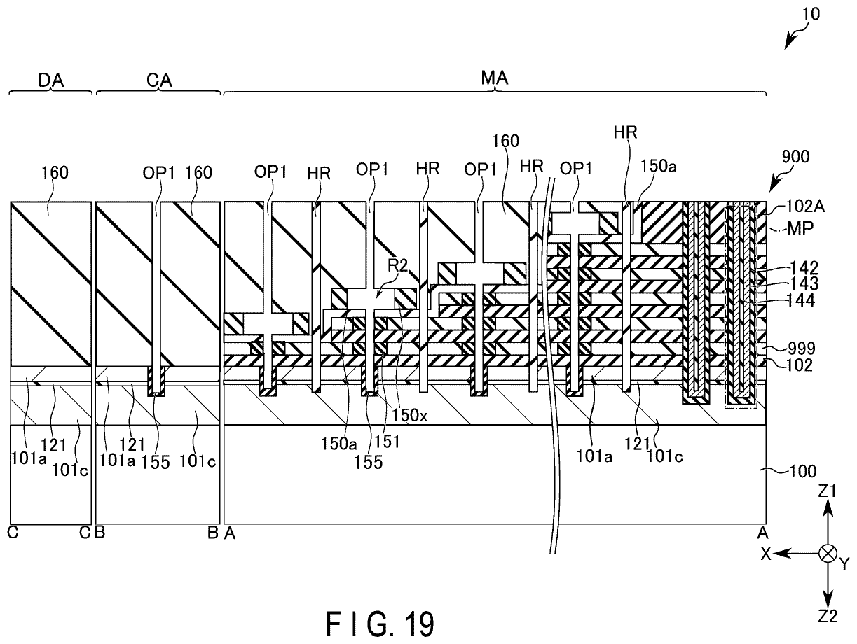

As shown in FIG. 19, the spacer film 150x is selectively etched (removed). The spacer film 150x further retreats in a direction parallel to the surface of the semiconductor substrate 100. As a result, the dimension of a recess R2 of the spacer film 150x in the direction parallel to the surface of the semiconductor substrate 100 is larger than the dimension of the insulator 151 in the direction parallel to the surface of the semiconductor substrate 100.

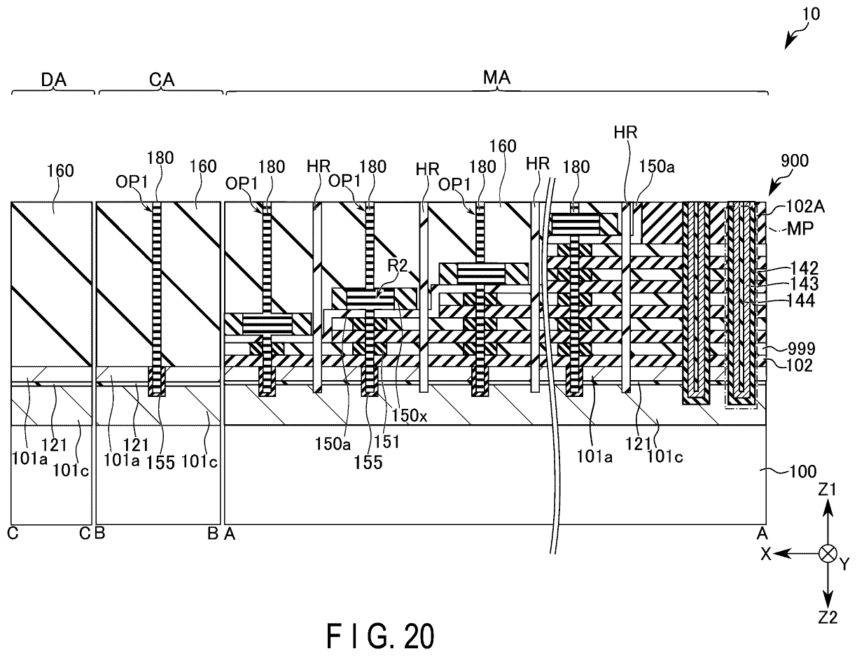

As shown in FIG. 20, in the hookup area and the contact area CA, the opening OP1 including the recess R2 is filled with a sacrificial member 180. The sacrificial member 180 is selectively removed from the upper surfaces of the insulating layers 160 and 102A by etching. An upper end of the sacrificial member 180 is aligned with the upper surface of the insulating layer 160. The material of the sacrificial member 180 is, for example, a semiconductor such as amorphous silicon.

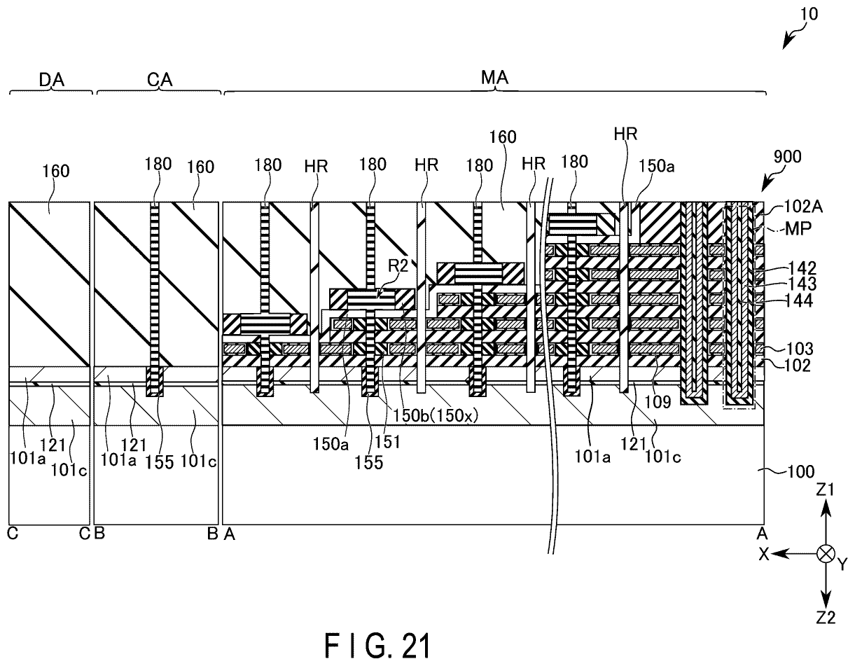

As shown in FIG. 21, a replacement process for forming the word line WL is executed. The sacrificial layer 999 is selectively removed via a slit (not shown) formed in the layer stack 900. The spacer film 150x is divided into a plurality of portions in the Y direction by the slit. The spacer film 150x is in contact with the slit. The support member HR suppresses collapse of the layer stack 900 from which the sacrificial layer 999 has been removed.

After removal of the sacrificial layer 999, an insulating layer 109 such as an aluminum oxide film is formed in the space from which the sacrificial layer 999 of the layer stack 900 has been removed such that the space is not filled. The conductive layer 103 is formed on the insulating layer 109 in the space from which the sacrificial layer 999 of the layer stack 900 is removed.

According to the present embodiment, in the hookup area, the spacer film 150x is removed simultaneously with the removal of the sacrificial layer 999. The space generated by the removal of the spacer film 150x is connected to the slit. The insulating layer 109 and the conductive layer 103 are formed in the space generated by the removal of the spacer film 150x. However, the space generated at the position of the spacer film 150x is larger than the space between the insulating layers 102. Therefore, the space generated at the position of the spacer film 150x is not closed by the insulating layer 109 and the conductive layer 103.

Thereafter, the insulating layer 109 and the conductive layer 103 in the slit (not shown) for the replacement processing are removed. At this time, in the hookup area, the insulating layer 109 and the conductive layer 103 in the space generated at the position of the spacer film 150x are removed simultaneously with the insulating layer 109 and the conductive layer 103 in the slit.

The slit is filled with an insulator such as silicon oxide. At the same time, the space generated at the position of the spacer film 150x is filled with the insulating layer 150b.

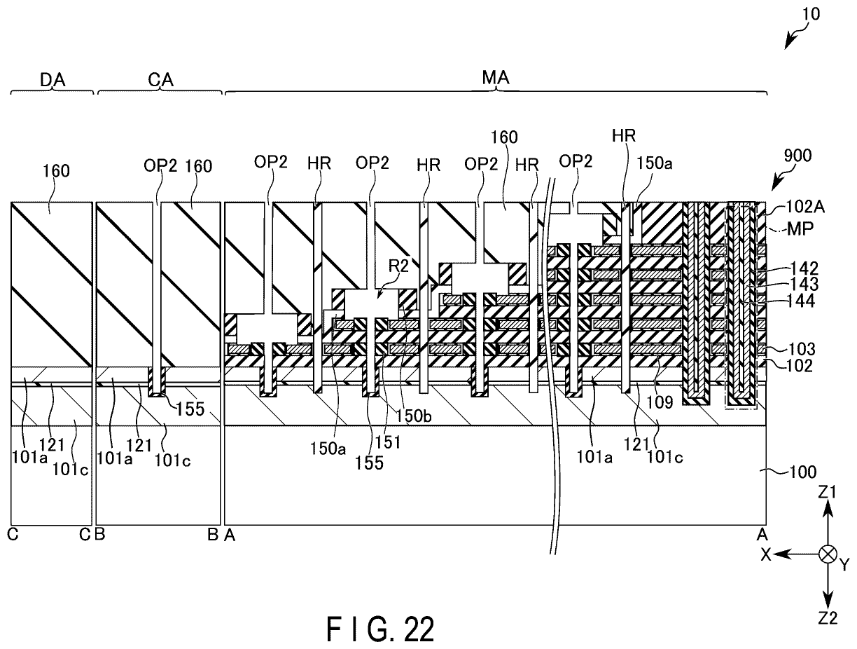

As shown in FIG. 22, the sacrificial member 180 is removed in the hookup area and the contact area CA of the memory cell array area MA. The openings OP2 are generated by the removal of the sacrificial member 180. At the bottom of the recesses R2, the insulating layer 150a and a part of the insulating layer 109 are removed via the openings OP2. As a result, in the hookup area, the terrace of the conductive layer 103 is exposed in each of the recesses R2.

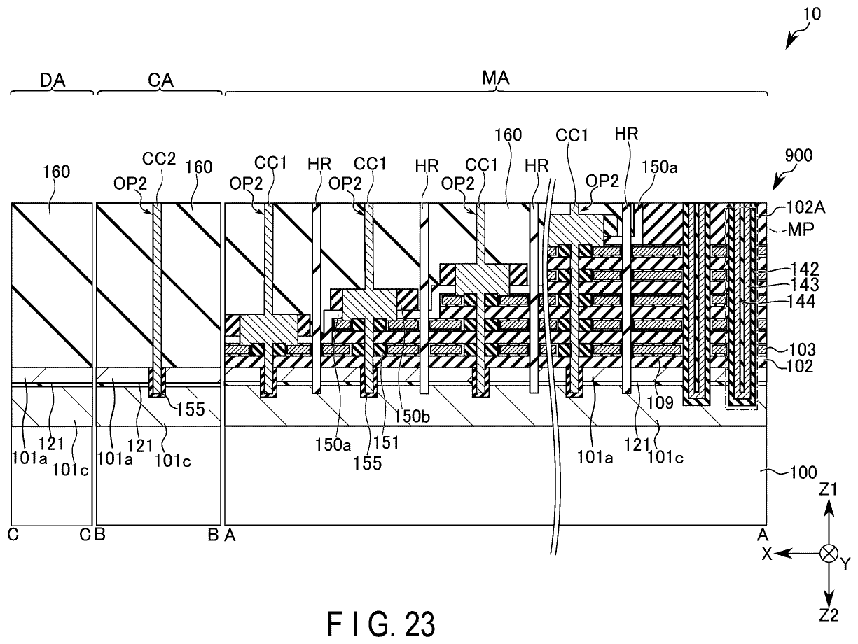

As shown in FIG. 23, the conductor is filled in the openings OP2 including the recesses R2. As a result, the contacts CC1 are formed in the openings OP2 of the hookup area.

Each of the formed contacts CC1 penetrates the one or more insulating layers 102 and the one or more conductive layers 103. The end (protruding portion 91) in the Z2 direction of the contact CC1 reaches the insulating film 155 in the semiconductor layers 101a and 101c. The contact CC1 is in contact with the terrace of the corresponding conductive layer 103 via a portion (projecting portion 90) projecting in the X direction (and the Y direction). As a result, the contact CC1 is electrically connected to the corresponding conductive layer 103.

The insulator 151 is provided between the side surface of the contact CC1 and the side surface of the conductive layer 103. As a result, the contact CC1 is electrically separated from the other conductive layer 103 other than the corresponding conductive layer 103.

In the contact area CA, the contact CC2 is formed in the insulating layer 160 substantially simultaneously with the formation of the contact CC1. The end of the contact CC2 reaches the inside of the insulating film 155 in the semiconductor layers 101a and 101c.

Thereafter, various conductors 104, 161, and 164 connected to the memory pillars MP and the contacts CC1 and CC2, the interconnects 106 and 163, the electrodes 111, and the insulating layers 162, 165, and 169 are sequentially formed by a known technique.

Through the above steps, the array chip 10 is formed.

The CMOS circuit chip 20 is manufactured separately from the manufacture of the array chip 10.

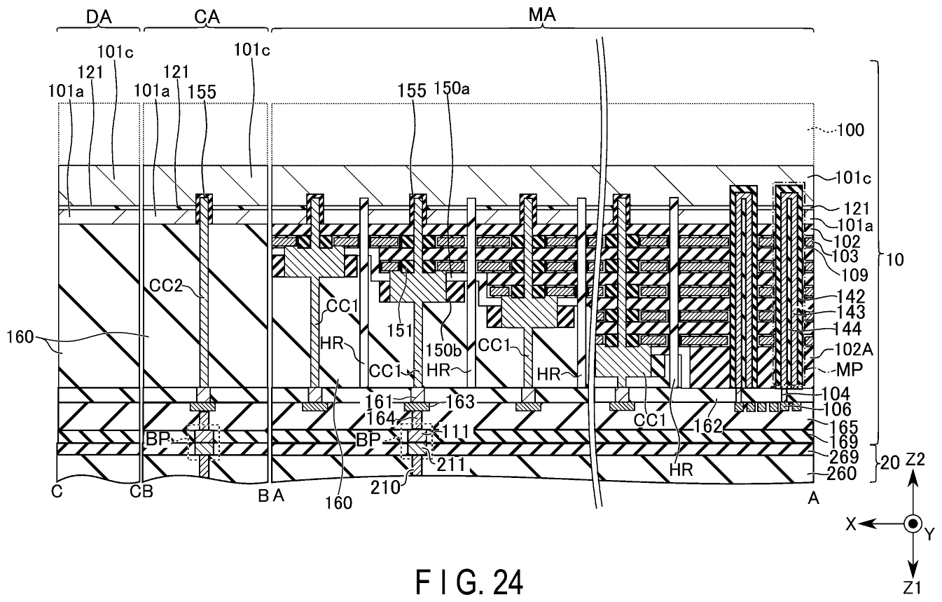

Each of FIGS. 24 to 31 is a cross-sectional process diagram showing a manufacturing process after the array chip 10 and the CMOS circuit chip 20 are bonded in the memory device 1 according to the present embodiment.

As shown in FIG. 24, the array chip 10 is bonded to the CMOS circuit chip 20 such that a surface facing the Z1 direction of the array chip 10 faces a surface facing the Z2 direction of the CMOS circuit chip 20. After bonding the two chips, the semiconductor substrate 100 of the array chip 10 is removed by grinding, wet etching, the CMP method, or the like. Thus, the semiconductor layer 101c is exposed in the Z2 direction.

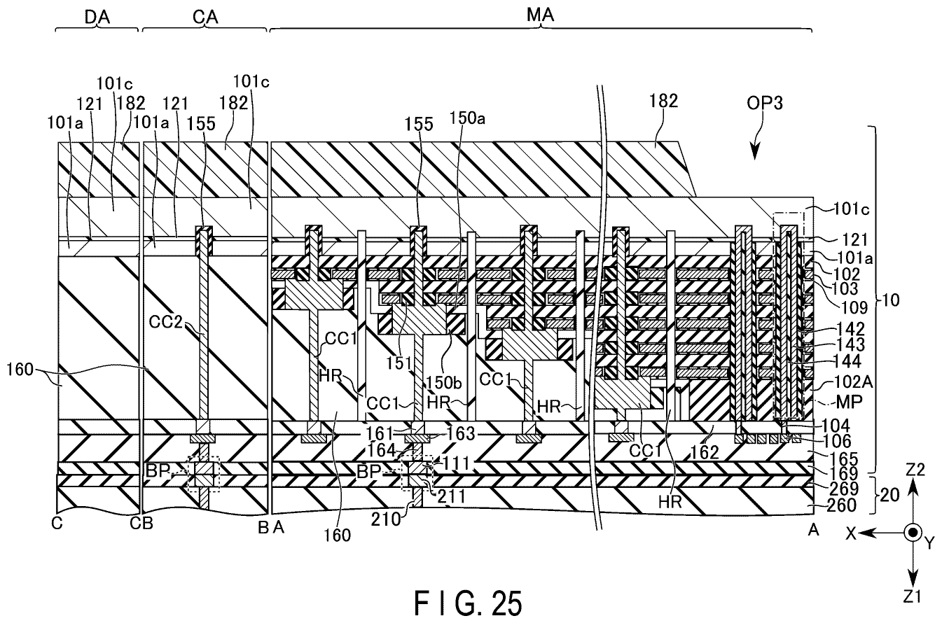

As shown in FIG. 25, a resist mask 182 is formed on the semiconductor layer 101c by photolithography and etching. An opening OP3 is formed in the resist mask 182. The opening OP3 is provided in the resist mask 182 so that the semiconductor layer 101c in the region where the memory pillar MP is formed in the memory cell array area MA is exposed.

In the hookup area, the contact area CA, and the plane separation area DA, the semiconductor layer 101c is covered with the resist mask 182.

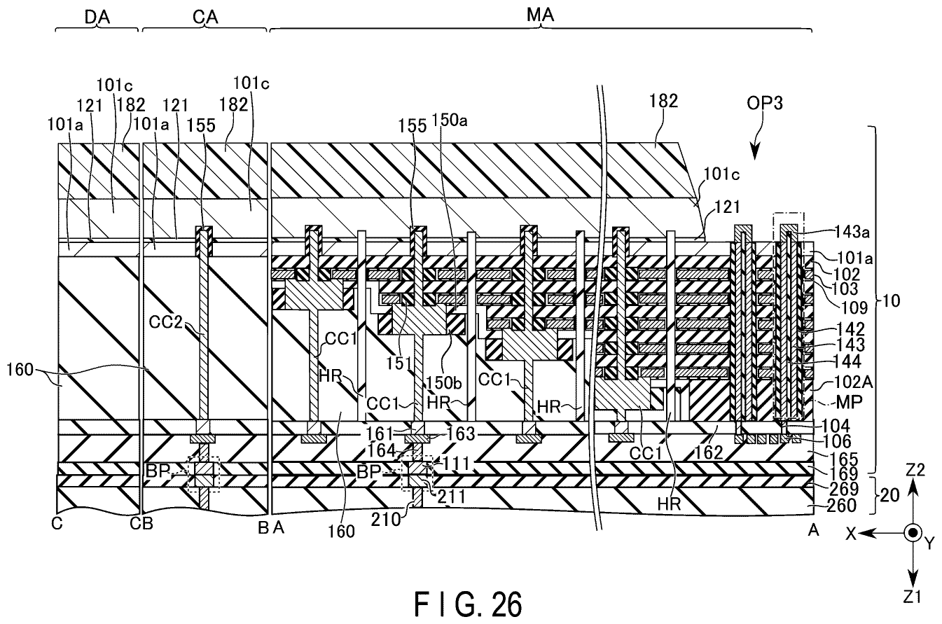

As shown in FIG. 26, the semiconductor layer 101c is partially removed (etched) by a reactive ion etching (RIE) method based on the pattern of the resist mask 182. As a result, the end portion on the Z2 direction side of the memory pillar MP is exposed. By the etching, a step is formed between the semiconductor layer 101a and the semiconductor layer 101c in the memory cell array area MA.

The exposed memory layer 142 of the memory pillar MP is removed by etching. As a result, the semiconductor layer 143 of the memory pillar MP is exposed.

Impurities (dopants) are added to the exposed part (exposed portion) 143a of the semiconductor layer 143 by ion implantation into the semiconductor layer 143.

Thereafter, laser annealing is applied to the exposed portion 143a to which impurities are added. As a result, the exposed portion 143a of the semiconductor layer 143 is crystallized.

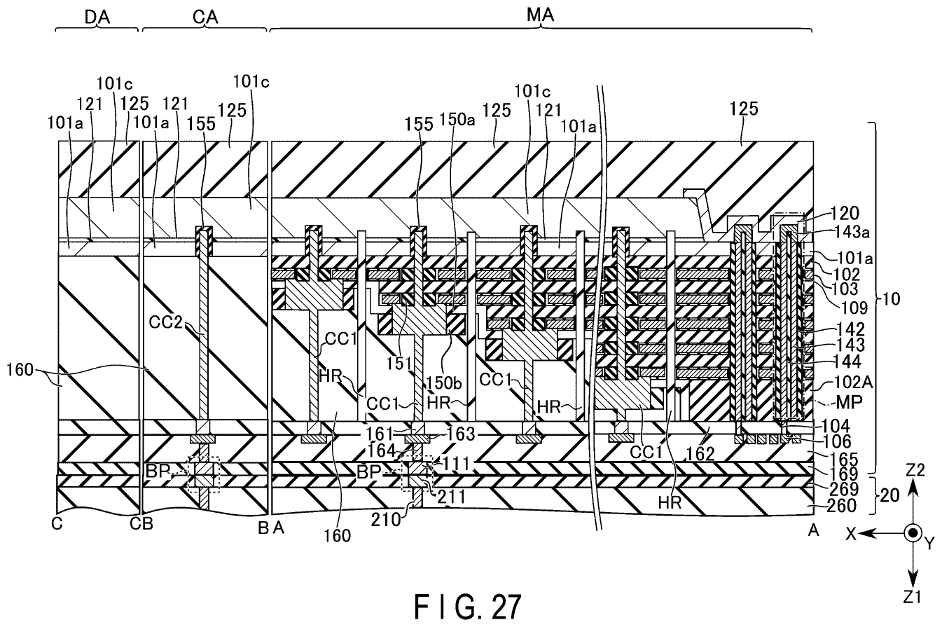

As shown in FIG. 27, after the resist mask 182 is removed, the metal layer 120 is formed on the semiconductor layers 101a and 101c by a physical vapor deposition (PVD) method, photolithography, and etching. The metal layer 120 extends from the surface facing the Z2 direction of the semiconductor layer 101a to the surface facing the Z2 direction of the semiconductor layer 101c via the side surface of the semiconductor layer 101c.

The insulating layer 125 is formed on the array chip 10 by the CVD method so as to cover the semiconductor layer 101c and the metal layer 120.

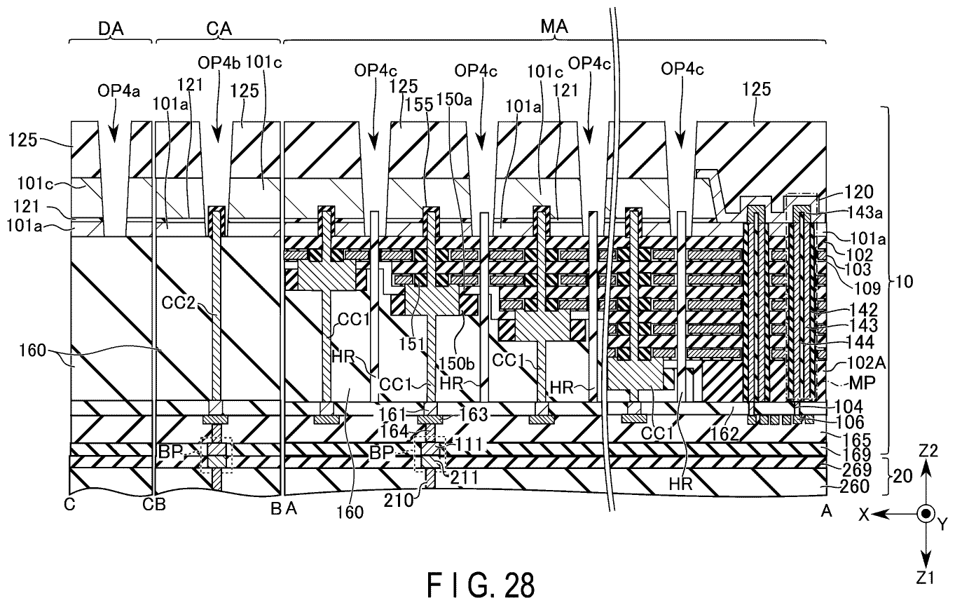

As shown in FIG. 28, in the plane separation area DA, slits (openings) OP4a for separating the planes PLN from each other are formed in the insulating layer 125, the semiconductor layer 101c, the insulating layer 121, and the semiconductor layer 101a. As a result, in the plane separation area DA, the semiconductor layers 101a and 101c are divided for each plane PLN. The slits OP4a has a grid-like structure when viewed from the Z direction. The slit OP4a has a forward tapered cross-sectional shape.

By the process simultaneously with the formation of the opening OP4a in the plane separation area DA, an opening OP4b is formed in the insulating layer 125, the semiconductor layer 101c, the insulating layer 121, and the semiconductor layer 101a in the contact area CA such that the end portion (insulating film 155) of the contact CC2 on the Z2 direction side is exposed. For example, the opening OP4b has a quadrangular or circular structure when viewed from the Z direction. The opening OP4b has a forward tapered cross-sectional shape.

In a process simultaneously with the dividing of the semiconductor layers 101a and 101c in the plane separation area DA, the slits OP4c are formed in the hookup area of the array chip 10 so as to penetrate the insulating layer 125, the semiconductor layer 101c, the insulating layer 121, and the semiconductor layer 101a in the Z direction.

The slits OP4c are formed to have a grid-like layout when viewed from the Z direction. The slits OP4c have a forward tapered cross-sectional shape.

The slits OP4c are provided in a region between two adjacent contacts CC1. For example, the slits OP4c are formed at positions overlapping the support members HR in the Z direction.

The insulating layer (uppermost insulating layer in the Z2 direction) 102 closest to the source line of the layer stack 900 is exposed through the slits OP4c. At the positions of the slits OP4c, a step (groove) can be formed in the exposed portion of the insulating layer 102 while etching for forming the slits OP4c.

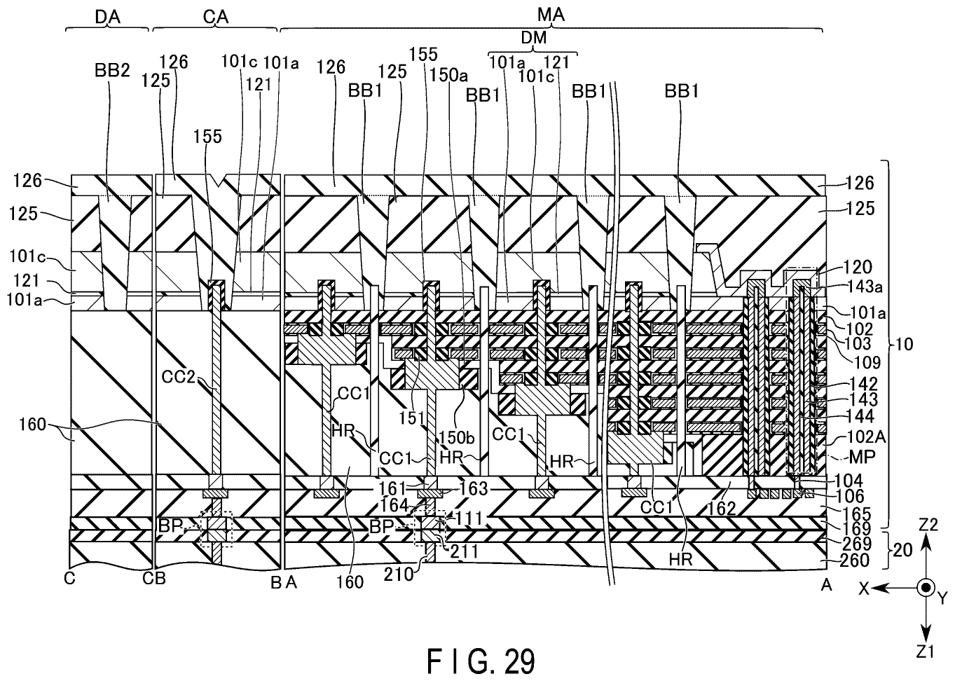

As shown in FIG. 29, the insulating layer 126 is formed on the insulating layer 125, the semiconductor layer 101c, the insulating layer 121, and the semiconductor layer 101a by the CVD method. The inside of the slit OP4a of the plane separation area DA, the inside of the opening OP4b of the contact area CA, and the inside of the slits OP4c of the hookup area (memory cell array area MA) are filled with the insulating layer 126.

In this manner, the separation member BB1 in the hookup area and the separation member BB2 in the plane separation area DA are formed in the slits OP4a and OP4c formed in the insulating layers 121 and 125 and the semiconductor layers 101a and 101c by the same process. The separation members BB1 and BB2 are insulators continuous with the insulating layer 126.

Note that the separation members BB1 and BB2 may be formed in a process different from the formation of the insulating layer 126. For example, members (insulators) for forming the separation members BB1 and BB2 are embedded in the slits OP4a and OP4c. Thereafter, the insulating layer 126 is formed on the insulating layer 125 and the separation members BB1 and BB2.

In a case where the separation members BB1 and BB2 are formed, gaps (voids) may be generated in the separation members BB1 and BB2.

The formed separation members BB1 and BB2 have a grid-like structure when viewed from the Z direction. The formed separation members BB1 and BB2 have a forward tapered cross-sectional structure according to the shapes of the slits OP4a and OP4c. In other words, in the separation members BB1 and BB2, the dimension along the X direction (or the Y direction) of the portion on the Z2 direction side (the array chip 10 side) is larger than the dimension along the X direction (or the Y direction) of the portion on the Z1 direction side (the CMOS circuit chip 20 side).

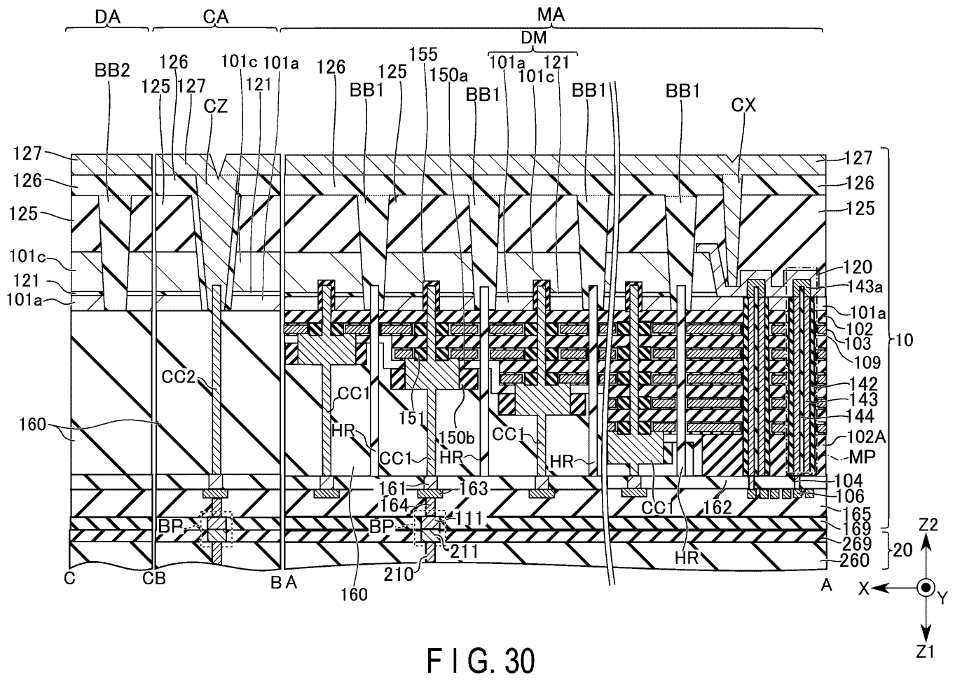

As shown in FIG. 30, an opening is formed in the insulating layers 125 and 126 by photolithography and etching at a position overlapping the metal layer 120 of the memory cell array area MA in the Z direction.

After the formation of the opening, the metal interconnect 127 is formed on the insulating layer 126. The interconnect 127 is processed into a predetermined shape by photolithography and etching.

The member of the interconnect 127 is embedded in the opening in the insulating layers 125 and 126. As a result, the contact CX is formed in the opening so as to be connected to the metal layer 120.

In the contact area CA, an opening is formed in the insulating layer 126 in a region overlapping the contact CC2 in the Z direction by a process simultaneously with the formation of the opening in the memory cell array area MA. At the time of forming the opening, the insulating film 155 covering the end portion on the Z2 direction side of the contact CC2 is removed. The interconnect 127 is formed on the insulating layer 126 so as to fill the opening. As a result, in the contact area CA, the contact CZ is formed so as to connect the interconnect 127 to the contact CC2. The contact CZ is in direct contact with the contact CC2. At the time of forming the opening OP4b (see FIG. 28), the insulating film 155 covering the end portion on the Z2 direction side of the contact CC2 may be removed.

For example, in the plane separation area DA, the interconnect 127 is formed on the insulating layer 126.

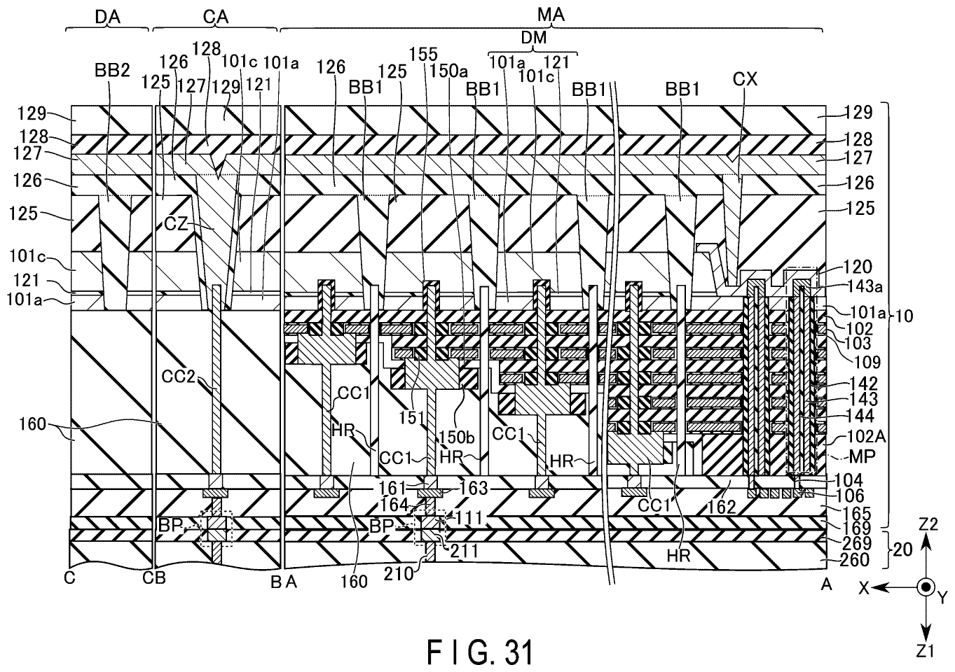

As shown in FIG. 31, the oxide insulating layer 128 is formed on the interconnect 127 and the insulating layer 126. The nitride insulating layer 129 is formed on the insulating layer 128.

Through the above steps, the memory device 1 according to the present embodiment is completed.

### (c) Summary

The contacts penetrating the conductive layers are used for connection between the conductive layers of the staircase structure and the interconnect of the memory device. In this case, the contacts are electrically separated from other members other than the corresponding conductive layer.

For example, in a case where the contacts reach the semiconductor layer overlapping the staircase structure in the Z direction, the contacts are electrically separated from the semiconductor layer by an insulating film formed between the semiconductor layer and the contacts.

In a case where the film thickness of the insulating film formed between the contacts and the semiconductor layer is thin, the contacts may be electrically connected to the semiconductor layer. In this case, the contacts can be electrically connected via the semiconductor layer.

If the insulating film between the contacts and the semiconductor layer is formed thick in order to ensure sufficient insulation between the contacts and the semiconductor layer, there is a possibility that volume expansion of the member due to the formation of the insulating film occurs in the staircase structure in the vicinity of the contacts. The insulating film is formed before the replacement process of the sacrificial layer with the conductive layer in the staircase structure (layer stack).

In this case, after the sacrificial layer is removed from the inside of the staircase structure in the replacement process, the insulating film having an expanded volume presses the space from which the sacrificial layer is removed. In other words, the space from which the sacrificial layer is removed is reduced. This can result in poor embedding of the conductive layer in the space from which the sacrificial layer is removed.

For this reason, it is difficult to increase the film thickness of the insulating film between the contacts and the semiconductor layer.

As shown in FIGS. 4 and 10 to 11B, in the memory device 1 according to the present embodiment, the separation member BB1 of the insulator is provided in the hookup area in which the staircase structure is disposed. The separation member BB1 divides the semiconductor layers 101a and 101c overlapping the staircase structure in the Z direction into a plurality of portions 101a-1, 101a-2, . . . , 101c-1, 101c-2, . . . , The separation member BB1 is provided between the contacts CC1 penetrating the staircase structure.

In this manner, the separation member BB1 electrically separates the contacts CC1 from each other. As a result, according to the present embodiment, electrical conduction between the contacts CC1 is prevented without an increase in the film thickness of the insulating film 155.

The diameter and cross-sectional area of the contacts CC1 formed so as to penetrate the staircase structure and the semiconductor layer 101a tend to decrease from the Z1 direction side toward the Z2 direction side. Therefore, the separation member BB1 having a tapered cross-sectional shape in which the dimension in the line width direction increases from the Z1 direction side toward the Z2 direction side can separate the semiconductor layer 101a with high positional accuracy while suppressing interference with the contacts CC1 between the contacts CC1.

On the other hand, the upper end of the contact CC1 may be located in a region between the surface (upper surface) on the Z2 direction side of the upper semiconductor layer 101c and the surface (lower surface) on the Z1 direction side of the semiconductor layer 101c of the two stacked semiconductor layers 101a and 101c. In other words, the contact CC1 exists at the position of the lower surface of the semiconductor layer 101c, but does not exist at the position of the upper surface of the semiconductor layer 101c. Therefore, even in a case where the upper end of the contact CC1 is located in the semiconductor layer 101c, the separation member BB1 having the forward tapered shape described above can separate the semiconductor layer 101c between the contacts CC1 with high positional accuracy while suppressing interference with the contacts CC1.

In addition, the separation member BB1 for separating the contacts CC1 is formed substantially simultaneously with the separation member BB2 for separating the planes PLN (between the source lines). Therefore, in the memory device 1 according to the present embodiment, even if the separation member BB1 is formed in the memory cell array area MA, an increase in the manufacturing process and an excessive increase in cost are avoided.

As described above, the memory device 1 according to the present embodiment can suppress defects such as a short circuit between members.

### (2) Second Embodiment

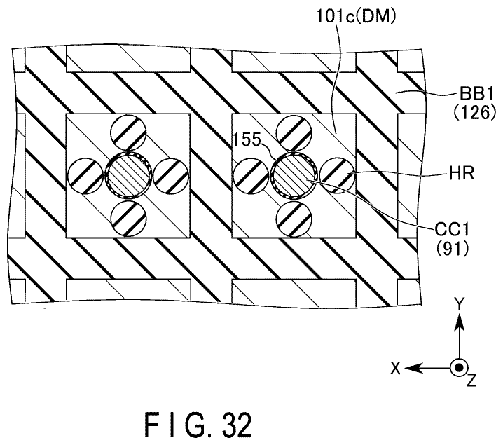

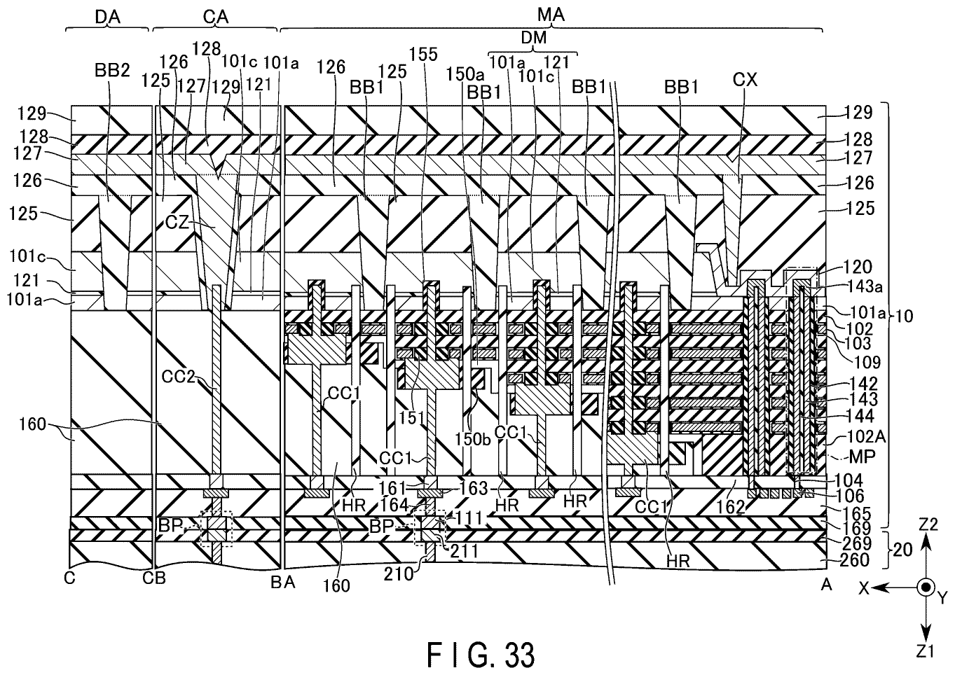

A memory device according to a second embodiment will be described with reference to FIGS. 32 and 33.

FIG. 32 is a plan view showing a structure example of the memory device 1 according to the present embodiment. FIG. 33 is a cross-sectional view showing a structure example of the memory device 1 according to the present embodiment.

As shown in FIGS. 32 and 33, support members HR may be formed in a region between a contact CC1 and a separation member BB1. The end of the support members HR in the Z2 direction are located in a semiconductor layer 101c of a dummy layer DM.

The separation member BB1 does not overlap the support members HR in the Z direction. The separation member BB1 surrounds the region of the dummy layer DM where the support members HR and the contacts CC1 are provided.

For example, one of the two support members HR sandwiching one contact CC1 in the X direction penetrates an insulating layer 150b.

According to the present embodiment, as in the first embodiment, in a hookup area of a memory cell array area MA, semiconductor layers 101a and 101c are independent for each corresponding contact CC1. As a result, the contacts CC1 are separated from each other.

As described above, the memory device according to the second embodiment can suppress a defect of the memory device substantially similarly to the first embodiment.

### (3) Third Embodiment

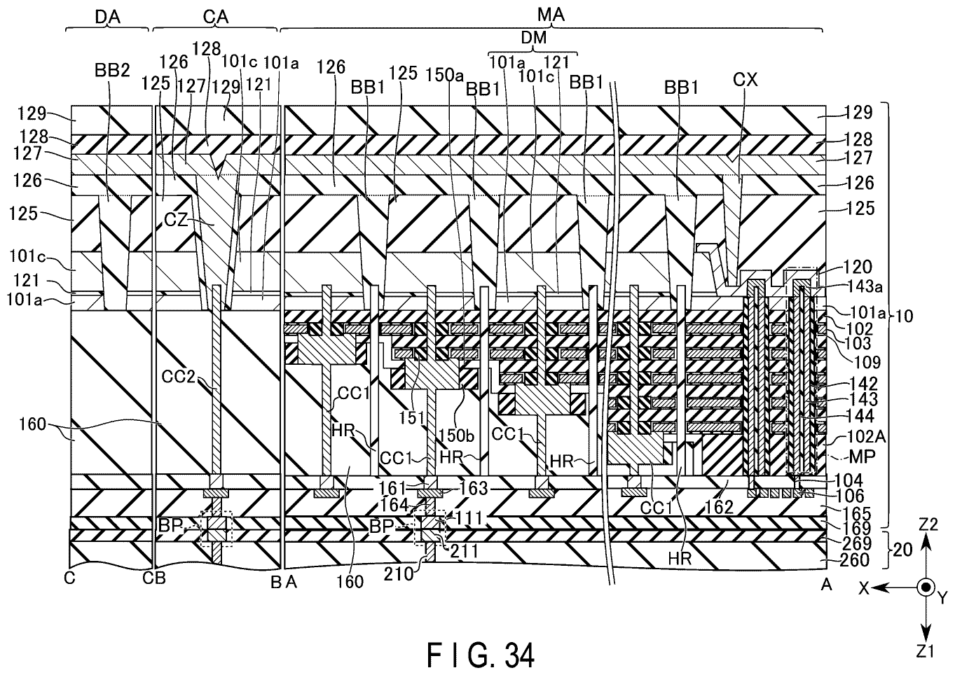

A memory device according to a third embodiment will be described with reference to FIG. 34.

FIG. 34 is a cross-sectional view showing a structure example of a memory device 1 according to the present embodiment.

As shown in FIG. 34, according to the present embodiment, an insulating film covering a protruding portion 91 of a contact CC1 is not provided in a dummy layer DM. A protruding portion 91 is in direct contact with semiconductor layers 101a and 101c.

As described above, in a hookup area, the semiconductor layers 101a and 101c are electrically separated for each corresponding contact CC1 by a grid-like separation member (insulator) BB1.

Therefore, even if the contact CC1 is in direct contact with the semiconductor layers 101a and 101c, the current does not flow between the semiconductor layer 101a functioning as a part of a source line SL and the contact CC1 and between the two contacts CC1 due to the interruption by the separation member BB1.

Therefore, the insulating film 155 of the above-described embodiment may not be provided between the contacts CC1 and the semiconductor layers 101a and 101c.

For example, in a manufacturing process of the memory device 1 according to the present embodiment, a process (WVG process) for forming the insulating film between the semiconductor layers 101a and 101c and the protruding portion 91 of the contact CC1 can be reduced. As a result, the memory device 1 according to the present embodiment can reduce the manufacturing cost of the memory device.

As described above, the memory device according to the third embodiment can suppress a defect of the memory device similarly to the above-described embodiments.

### (4) Fourth Embodiment

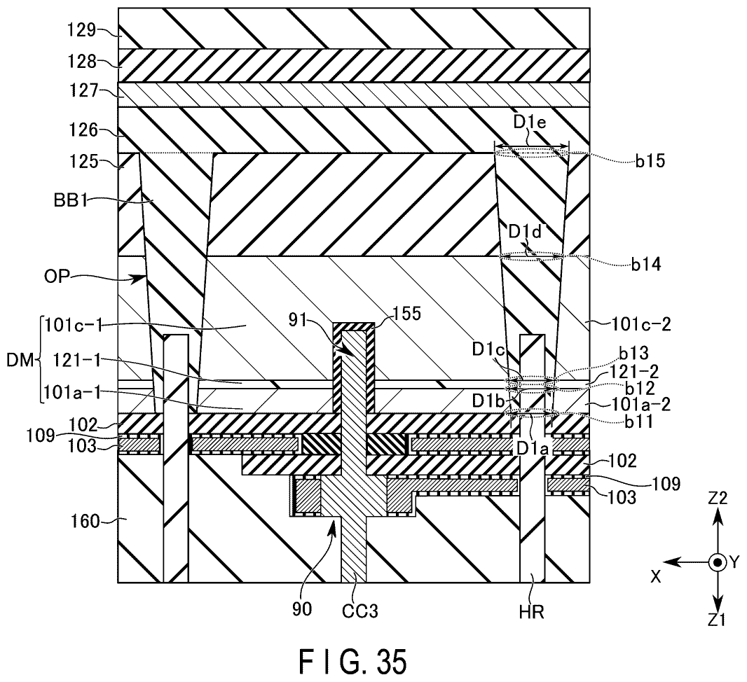

A memory device and a method of manufacturing the memory device according to a fourth embodiment will be described with reference to FIGS. 35 to 44.

### (a) Structural Example

FIG. 35 is a cross-sectional view showing a structure of contacts CC3 and a separation member BB1 in a hookup area of a memory cell array 11 in the memory device 1 according to the present embodiment.

As shown in FIG. 35, in the memory device 1 according to the present embodiment, the contacts (contact plugs) CC3 are provided in the hookup area in the memory cell array area MA. The contacts CC3 penetrate one or more insulating layers 102 and one or more conductive layers 103 in a staircase structure of the hookup area, similarly to the above-described embodiments.

In the present embodiment, the structure of the contacts CC3 is different from the structure of the contacts CC1 of the memory device 1 according to other embodiments. The projecting portion 90 on a side surface of the contact CC3 contacts a side surface of a conductive layer 103 (a word line WL and select gate lines SGD and SGS). The conductive layer 103 has a portion protruding toward the Z1 direction side at a contact portion with the contact CC3.

As a result, in the memory device 1 according to the present embodiment, the electrical connection between the contact CC3 and the conductive layer 103 is secured.

A support member HR may be disposed in a region between the separation member BB1 and the contact CC3 similarly to the structure of FIG. 32.

### (b) Manufacturing Method

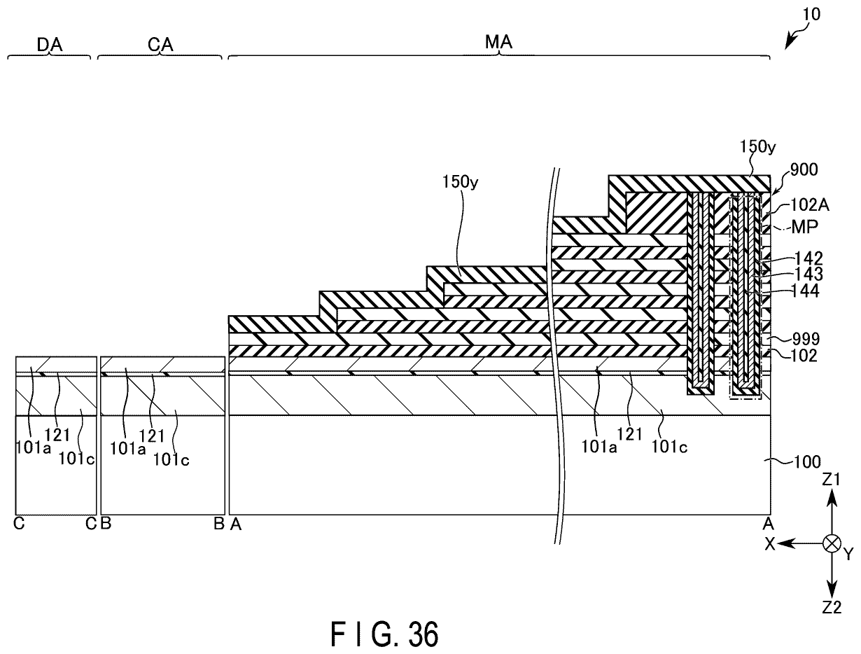

A method of manufacturing the memory device 1 according to the present embodiment will be described with reference to FIGS. 36 to 44. Each of FIGS. 36 to 44 is a cross-sectional process diagram showing a manufacturing process of the memory device 1 according to the present embodiment.

As shown in FIG. 36, semiconductor layers 101a and 101c and an insulating layer 121 are formed on a semiconductor substrate 100, similarly to the method of manufacturing the memory device 1 according to the first embodiment. A layer stack 900 including a plurality of insulating layers 102 and 102A and a plurality of sacrificial layers 999 is formed on the semiconductor layer 101a. A staircase structure is formed at an end portion in the X direction of the layer stack 900.

A spacer film 150y is formed so as to cover the layer stack 900. The material of the spacer film 150y is, for example, the same as the material of the sacrificial layers 999 (for example, silicon nitride).

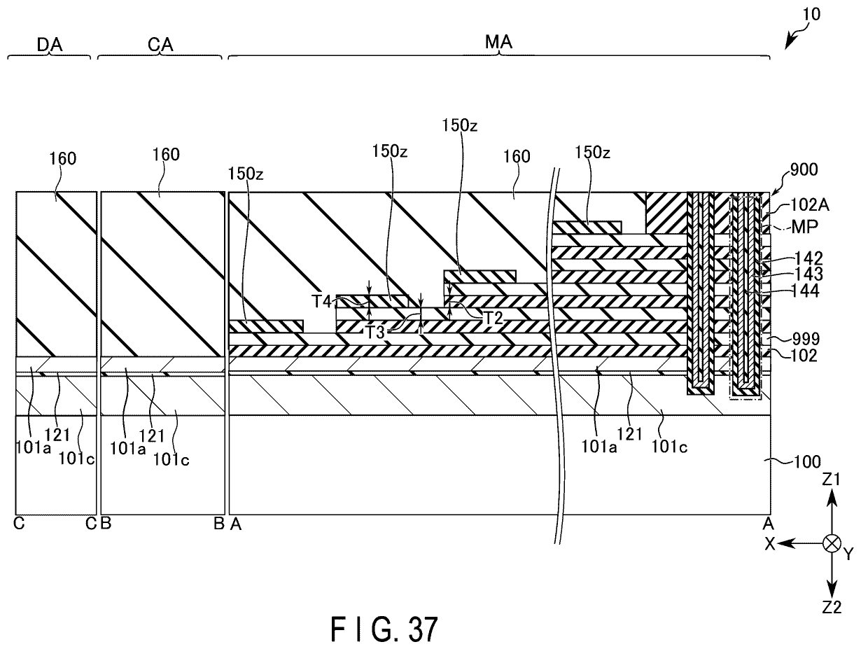

The spacer film 150y is processed into a predetermined shape by photolithography and RIE. As a result, as shown in FIG. 37, a plurality of spacer films 150z are formed so as to be individualized for each step of the staircase structure. For example, a film thickness T4 of the spacer film 150z is substantially the same as the film thickness T2 of the insulating layer 102.

An insulating layer 160 is formed on the layer stack 900 and the spacer films 150z. The insulating layer 160 is planarized by etch-back and a CMP method so that an upper surface of the insulating layer 160 is aligned with an upper surface of the layer stack 900. The material of the insulating layer 160 is, for example, silicon oxide formed using TEOS.

In the contact area CA and the plane separation area DA, the insulating layer 160 is formed on the semiconductor layer 101a.

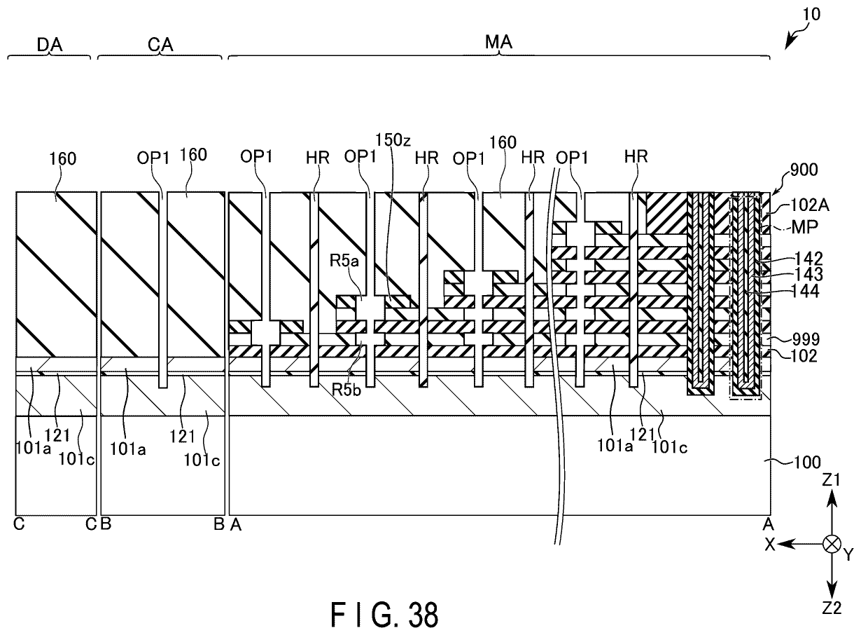

As shown in FIG. 38, in the hookup area of the memory cell array area MA, a plurality of support members HR are formed so as to penetrate the staircase structure. Lower ends of the support members HR reach the semiconductor layer 101c.

Among the support members HR, the support members HR at the positions where the contacts CC3 are to be formed are removed. As a result, openings OP1 are formed in the regions where the contacts CC3 are to be formed. For example, the semiconductor layers 101a and 101c are exposed at the bottoms of the openings OP1.

In the contact area CA, the opening OP1 through which the semiconductor layers 101a and 101c are exposed at the bottom is formed at a position where a contact CC2 is formed simultaneously with the openings OP1 in the hookup area.

The spacer films 150z are selectively etched through the openings OP1. As a result, the spacer films 150z retreat in a direction parallel to the surface of the semiconductor substrate 100. The sacrificial layers 999 made of the same material as the spacer films 150z are also retracted in a direction parallel to the surface of the semiconductor substrate 100 similarly to the spacer films 150z.

As a result, in the openings OP1, a groove R5a is formed corresponding to the position of the portion to be a terrace of a conductive layer 103. The groove R5b is formed between the two insulating layers 102 adjacent in the Z direction.

For example, the dimension of the groove R5a is larger than the dimension of the groove R5b in the Z direction.

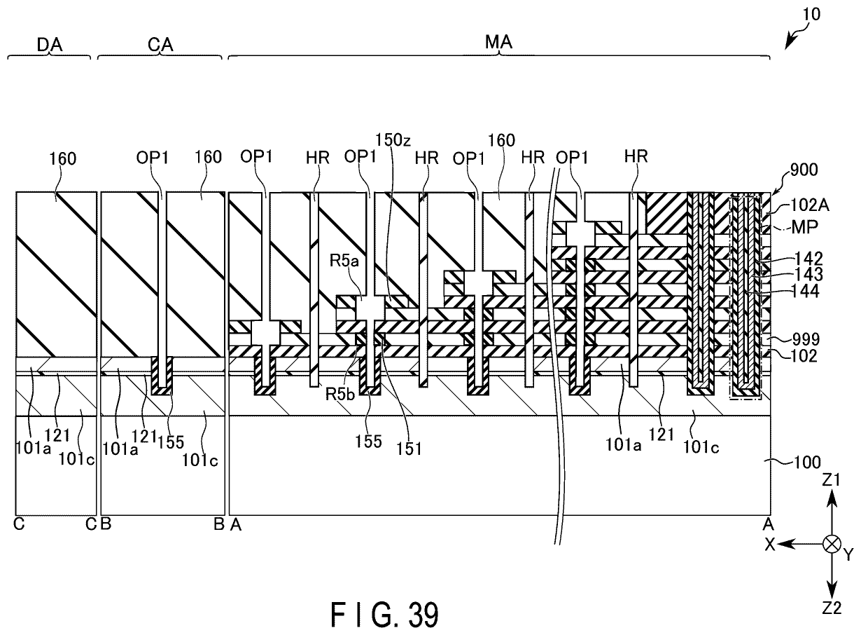

As shown in FIG. 39, the insulator 151 is formed in the opening OP1 including the recesses R5a and R5b.

Wet etching is selectively performed on the insulator 151. The insulator 151 remains in the groove R5b of the opening OP1. The insulator 151 is removed from the inside of the groove R5a having a large dimension.

Thereafter, an oxidation treatment by the WVG method is executed. The exposed portions of the semiconductor layers 101a and 101c and the insulating layer 121 are oxidized. As a result, an insulating film 155 is formed on the semiconductor layers 101a and 101c and the insulating layer 121 at the bottom of the opening OP1.

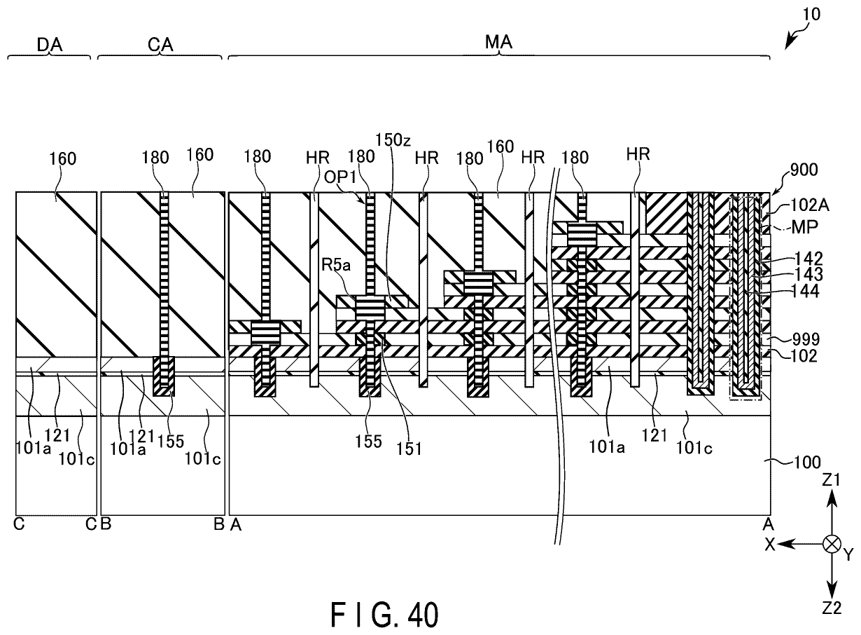

As shown in FIG. 40, a sacrificial member 180 is filled in the opening OP1 including the groove R5a. The sacrificial member 180 is, for example, amorphous silicon. The groove R5a is closed by the sacrificial member 180.

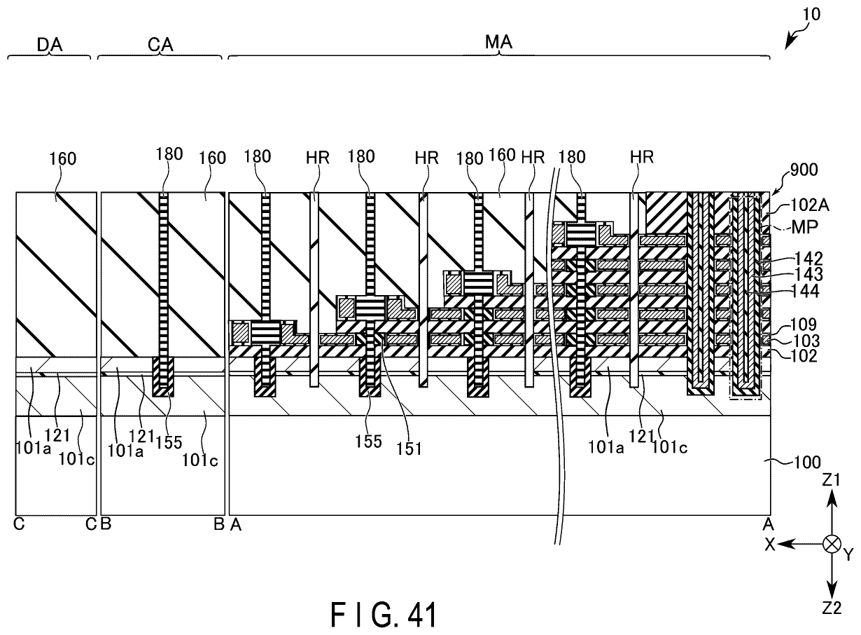

As shown in FIG. 41, a replacement process for forming the conductive layer 103 is executed. As a result, the insulating layer 109 and the conductive layer (word line and select gate line) 103 are formed in the space from which the sacrificial layer 999 is removed in the layer stack 900.

As described above, the material of the spacer films 150z is the same as the material of the sacrificial layer 999. Therefore, the spacer films 150z are also removed together with the sacrificial layer 999. In the hookup area, the conductive layer 103 and the insulating layer 109 are also formed in the space from which the spacer film 150z has been removed.

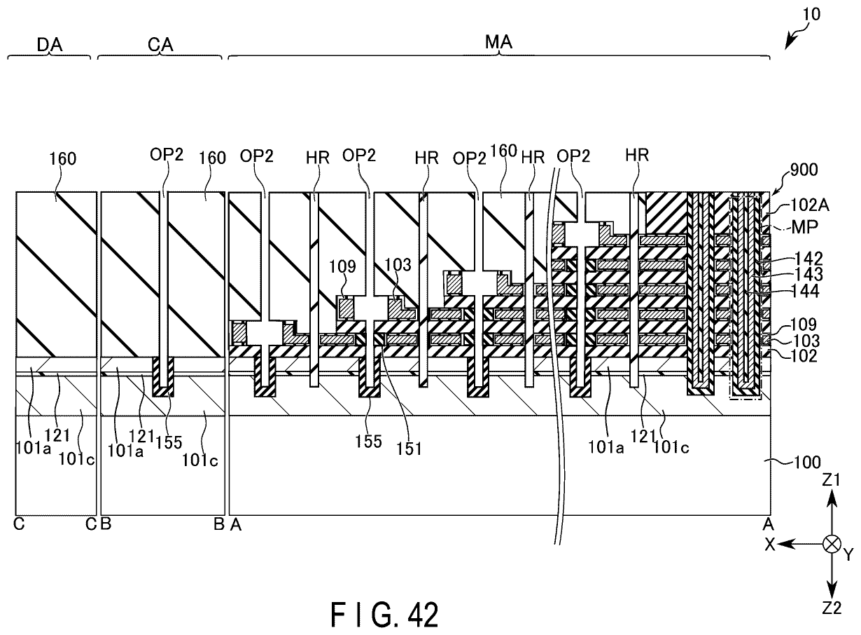

As shown in FIG. 42, the sacrificial member 180 is selectively removed in the hookup area. As a result, openings OP2 are formed. The insulating layer 109 covering the side surface of the conductive layer 103 is exposed to openings OP2. In the openings OP2, the exposed insulating layer 109 is selectively removed. As a result, the side surface of the conductive layer 103 is exposed in the opening OP2.

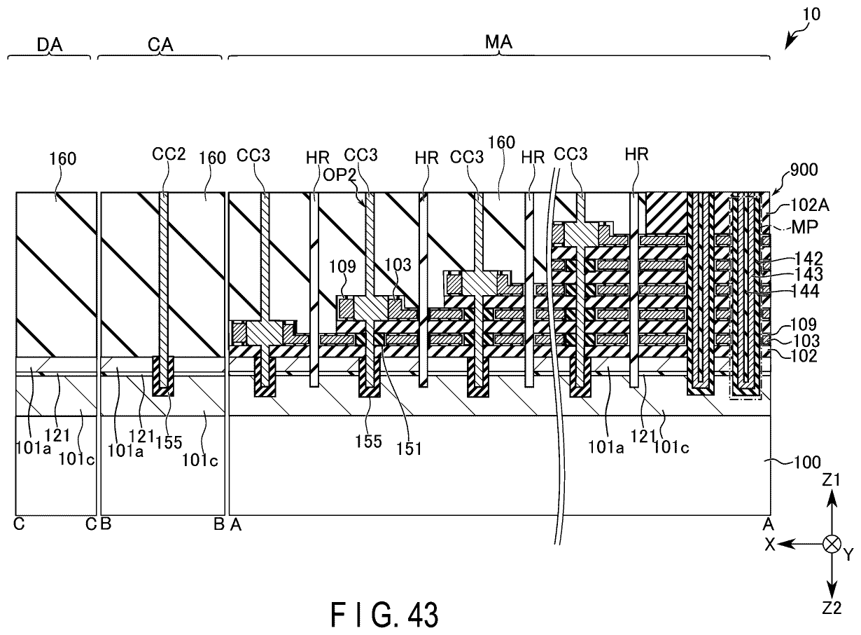

As shown in FIG. 43, the openings OP2 are filled with the contacts CC3. As described above, in the hookup area (staircase structure), the insulating layer 109 is removed from the side surface of the conductive layer 103. Therefore, the contacts CC3 filled in the openings OP2 are in direct contact with the conductive layer 103. As a result, electrical connection between the contacts CC3 and the conductive layer 103 is secured.

As a result, the contacts CC3 are formed so as to be connected to the corresponding conductive layers 103 respectively. The side surface of each of the contacts CC3 is in direct contact with the side surface of the corresponding conductive layer 103.

In the contact area CA, a contact CC2 is formed in the insulating layer 160 substantially simultaneously with the formation of the contacts CC3.

The ends of the contacts CC2 and CC3 reach the inside of the insulating film 155 in the semiconductor layers 101a and 101c.

Thereafter, in an array chip 10, a bit line BL, other interconnects 163, and the like are formed similarly to the above-described embodiments. After the array chip 10 is formed by the above process, the array chip 10 is bonded to a CMOS circuit chip 20 similarly to the above-described embodiments.

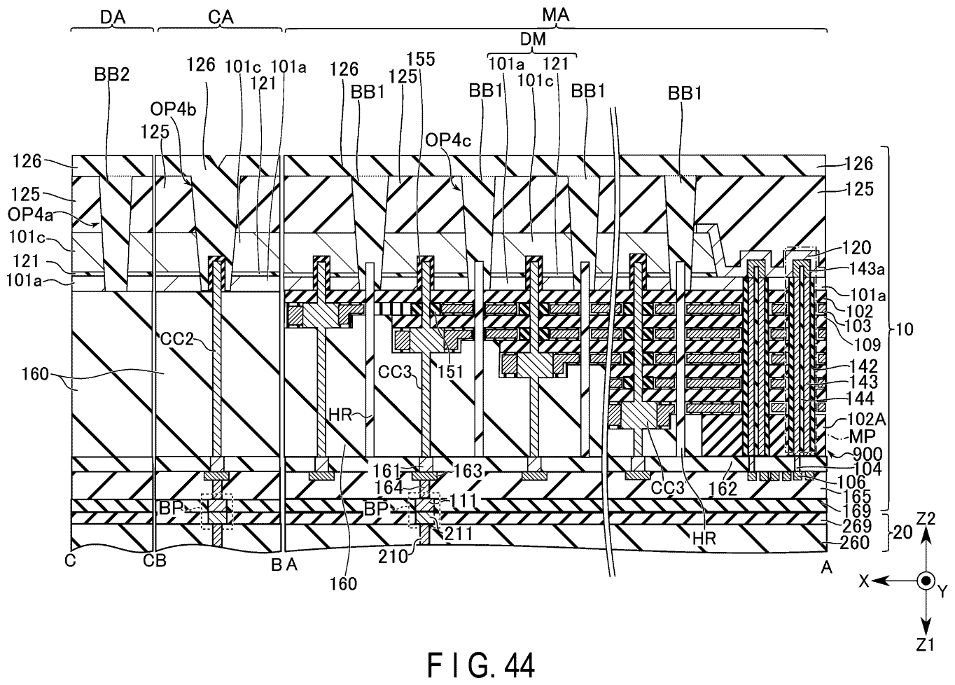

Thereafter, as shown in FIG. 44, the source line including the metal layer 120 and the portion of the semiconductor layer 101a is formed by substantially the same process as the manufacturing process of FIGS. 24 to 27 described above. After forming the source line, the separation member BB1 is formed in the hookup area of the memory cell array area MA substantially simultaneously with the formation of the separation member BB2 in the plane separation area DA by substantially the same process as the manufacturing process of FIGS. 28 and 29 described above. Thus, the semiconductor layers 101a and 101c are divided into a plurality of portions in the hookup area.

As a result, the adjacent contacts CC3 are electrically separated by the separation member BB1.

Thereafter, the memory device 1 according to the present embodiment is completed by substantially the same process as the manufacturing process of FIGS. 30 and 31 described above.

According to the present embodiment, the oxidation process of the semiconductor layers 101a and 101c by the WVG method in FIG. 39 may be omitted.

The memory device 1 according to the present embodiment can obtain substantially the same effects as those of the above-described embodiments.

### (5) Fifth Embodiment

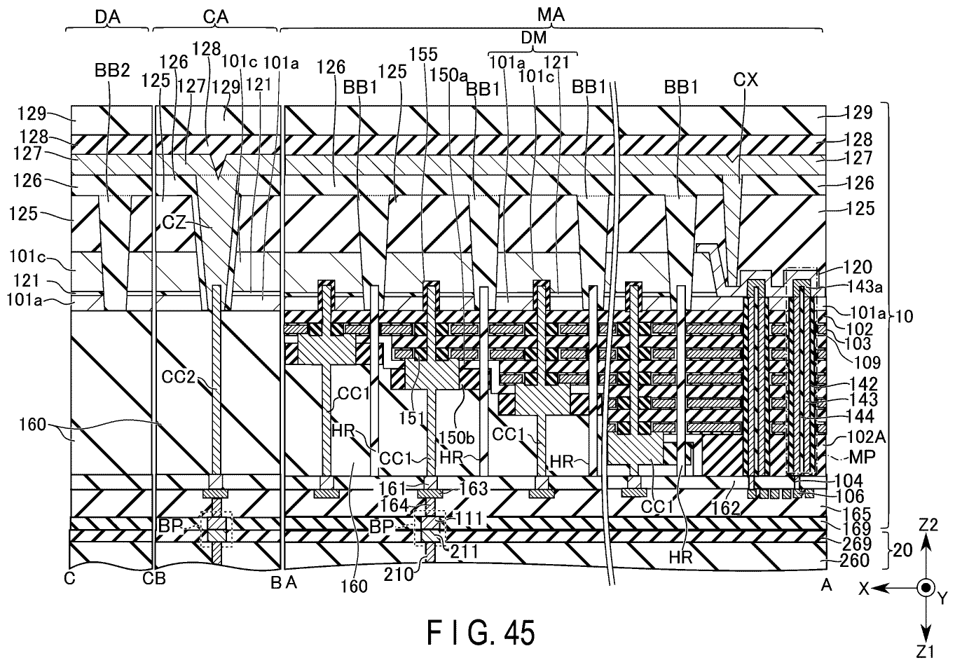

A memory device according to a fifth embodiment will be described with reference to FIG. 45.

FIG. 45 is a cross-sectional view showing a structure example of a memory device 1 according to the present embodiment.

As shown in FIG. 45, support members HR arranged in the X direction with respect to contacts CC1 may be disposed in a hookup area of a memory cell array area MA so as to penetrate insulating layers 150a and 150b. In the hierarchy in which the support member HR penetrates a terrace of a conductive layer 103, a side surface of the support member HR is in contact with the insulating layers 150a and 150b. The end portion in the Z2 direction of the support member HR is in contact with the separation member BB1.

Note that the contacts CC1 may be arranged so that the contacts CC1 are aligned in an oblique direction with respect to the X-Y plane in the hookup area.

The memory device 1 according to the present embodiment can obtain the same effects as those of the above-described embodiments.

### (6) Others

In the above-described embodiments, a memory device 1 having a configuration in which one CMOS circuit chip 20 is provided for one array chip 10 is described as an example. However, the memory device 1 according to the embodiments may have a configuration in which a plurality of CMOS circuit chips 20 are provided for one array chip 10, or may have a configuration in which a plurality of array chips 10 are provided for one CMOS circuit chip 20. While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first chip including a substrate and a circuit on the substrate; and
a second chip bonded to the first chip, wherein the second chip includes
a layer stack including a plurality of conductive layers arranged apart from each other in a first direction perpendicular to a surface of the second chip, and a memory pillar penetrating the plurality of conductive layers,
a first semiconductor layer provided above the layer stack in the first direction, the first semiconductor layer and a part of a source line being arranged in a second direction parallel to the surface of the second chip,
a first contact that penetrates at least a first conductive layer among the plurality of conductive layers, is connected to the first conductive layer, and includes a portion located in the first semiconductor layer on a side opposite to the first chip with respect to the first conductive layer,
a second contact that penetrates at least a second conductive layer among the plurality of conductive layers, is connected to the second conductive layer, and includes a portion located in the first semiconductor layer on a side opposite to the first chip with respect to the second conductive layer, the first contact and the second contact being arranged in the second direction, and
a first separation member that separates the first semiconductor layer in the second direction between the first contact and the second contact,
the first separation member includes a first portion located along a surface on a first chip side of the first semiconductor layer and a second portion located along a surface on a side opposite to the first chip of the first semiconductor layer, and
a first dimension along the second direction of the second portion is larger than a second dimension along the second direction of the first portion.

2. The memory device according to claim 1, wherein
the second chip further includes
a second semiconductor layer provided in a same hierarchy as the first semiconductor layer, and
a second separation member that is provided between the first semiconductor layer and the second semiconductor layer and separates the first semiconductor layer and the second semiconductor layer from each other,
the first semiconductor layer belongs to a first memory cell array, and
the second semiconductor layer belongs to a second memory cell array different from the first memory cell array.

3. The memory device according to claim 2, wherein
the second separation member includes a third portion located along surfaces on the first chip side of the first and second semiconductor layers, and a fourth portion located along surfaces on the side opposite to the first chip of the first and second semiconductor layers, and
a third dimension along the second direction of the fourth portion is larger than a fourth dimension along the second direction of the third portion.

4. The memory device according to claim 2, wherein
a material of the second separation member is same as a material of the first separation member.

5. The memory device according to claim 1, wherein
the first separation member includes
a fifth portion extending in the second direction, and
a sixth portion extending in a third direction parallel to the surface of the second chip and intersecting the second direction.

6. The memory device according to claim 1, wherein
the second chip further includes a third semiconductor layer provided above the first semiconductor layer and separated from the first semiconductor layer,
each of the first and second contacts penetrates the first semiconductor layer,
an upper end of each of the first and second contacts is located in the third semiconductor layer, and
the first separation member further separates the third semiconductor layer into a plurality of portions in the second direction between the first contact and the second contact.

7. The memory device according to claim 6, wherein
the second chip further includes a metal layer provided on the part of the source line, the third semiconductor layer and the metal layer being arranged in the second direction, and
the metal layer functions another part of the source line and overlaps the memory pillar via the part of the source line in the first direction.

8. The memory device according to claim 1, wherein
the second chip further includes a first insulating layer provided above the first semiconductor layer, and
the first separation member is continuous with the first insulating layer.

9. The memory device according to claim 8, wherein
the second chip further includes a third contact that penetrates at least a third conductive layer among the plurality of conductive layers, is connected to the third conductive layer, and includes a portion located in the first semiconductor layer on a side opposite to the first chip with respect to the third conductive layer, the first contact and the third contact being arranged via the second contact in the second direction,
the first insulating layer extends in the second direction above the second contact, and
the first separation member being continuous with the first insulating layer further separates the first semiconductor layer in the second direction between the second contact and the third contact.

10. The memory device according to claim 8, wherein
a material of the first separation member is same as a material of the first insulating layer.

11. The memory device according to claim 1, wherein
the first semiconductor layer includes
a seventh portion in which the first contact is located, and
an eighth portion in which the second contact is located, and
the first separation member electrically separates the seventh portion from the eighth portion.

12. The memory device according to claim 11, wherein
the first separation member has a grid-like structure when viewed from the first direction,
each of the seventh and eighth portions is surrounded by the first separation member, and
each of the seventh and eighth portions has a quadrangular structure when viewed from the first direction.

13. The memory device according to claim 1, wherein
the second chip further includes
a first insulating film portion provided between the first contact and the first semiconductor layer, and
a second insulating film portion provided between the second contact and the first semiconductor layer.

14. The memory device according to claim 1, wherein
the first and second contacts are in contact with the first semiconductor layer.

15. The memory device according to claim 1, wherein
the second chip further includes a support member penetrating at least one conductive layer among the plurality of conductive layers, and
the support member overlaps the first separation member in the first direction.

16. The memory device according to claim 1, wherein
the second chip further includes a first support member penetrating at least one conductive layer among the plurality of conductive layers,
the first support member is provided between the first contact and the first separation member in the second direction, and
a portion of the first support member on a side opposite to the first chip with respect to the conductive layers is located in the first semiconductor layer.

17. The memory device according to claim 1, wherein
the first contact includes a projecting portion projecting in the second direction,
the first conductive layer includes a terrace that is not overlapping the plurality of conductive layers other than the first conductive layer on the first chip side,
the projecting portion is in contact with a surface on the first chip side of the terrace,
the second conductive layer is provided between the first semiconductor layer and the first conductive layer,
the first contact penetrates the second conductive layer, and
a first insulator is provided between the first contact and a side surface of the second conductive layer.

18. The memory device according to claim 1, wherein
the second conductive layer is provided between the first semiconductor layer and the first conductive layer,
the first contact is in contact with a side surface of the first conductive layer,
the first contact penetrates the second conductive layer, and
a first insulator is provided between the first contact and a side surface of the second conductive layer.

19. A memory device comprising:
a first chip including a substrate and a circuit on the substrate; and
a second chip bonded to the first chip, wherein the second chip includes
a layer stack including a plurality of conductive layers arranged apart from each other in a first direction perpendicular to a surface of the second chip, and a memory pillar penetrating the plurality of conductive layers,
a semiconductor layer provided above the layer stack in the first direction,
a first contact that penetrates at least a first conductive layer among the plurality of conductive layers, is connected to the first conductive layer, and includes an upper end located in the semiconductor layer,
a second contact that penetrates at least a second conductive layer among the plurality of conductive layers, is connected to the second conductive layer, and includes an upper end located in the semiconductor layer, the first contact and the second contact being arranged in a second direction parallel to the surface of the second chip, and
a separation member that separates the semiconductor layer in the second direction between the first contact and the second contact,
the separation member includes a first portion located along a surface on a first chip side of the semiconductor layer and a second portion located along a surface on a side opposite to the first chip of the semiconductor layer, and
a first dimension along the second direction of the second portion is larger than a second dimension along the second direction of the first portion.

20. The memory device according to claim 19, wherein
portions included in the semiconductor layer, separated from each other by the separation member, and in which the upper ends of the first contact and the second contact are located are not electrically connected to any member on a side opposite to the first chip.
